(19) United States
(12) Patent Application Publication
(10) Pub. No.: US 2025/0374517 A1
(43) Pub. Date: Dec. 4, 2025

(54) STACKED CIM DRAM, MEMORY INCLUDING SAME, AND METHOD OF OPERATING SAME

(71) Applicant: TAIWAN SEMICONDUCTOR MANUFACTURING COMPANY, LTD., Hsinchu (TW)

(72) Inventors: Yi-Chun SHIH, Hsinchu (TW); Yih WANG, Hsinchu (TW)

(21) Appl. No.: 18/731,975

(22) Filed: Jun. 3, 2024

(51) Int. Cl. H10B 12/00; G11C 11/4096; H01L 23/00; H01L 25/00; H01L 25/065; H01L 25/18; H10B 80/00

(52) U.S. Cl. CPC H10B 12/315; G11C 11/4096; H01L 24/08; H01L 24/80; H01L 25/0657; H01L 25/18; H01L 25/50; H10B 12/0335; H10B 12/05; H10B 80/00; H01L 2224/08145; H01L 2224/80895; H01L 2224/80896; H01L 2924/1431; H01L 2924/1436

(57) ABSTRACT

A memory includes a logic circuit having a first input, a second input, and an output; and a memory circuit, including: a transistor coupled to the logic circuit, the transistor having a semiconductor layer including a source and a drain; and a storage node having a first connection, a second connection, and a third connection. The source or the drain of the transistor is coupled to the first connection of the storage node, the logic circuit includes one or more transistors in an active region of a substrate, the one or more transistors being front-end of line (FEOL) devices, and the semiconductor layer and the storage node are in back-end of line (BEOL) layers over the substrate.

### BACKGROUND

Recent developments in the field of artificial intelligence have resulted in various products and/or applications including, e.g., speech recognition, image processing, machine learning, natural language processing, and the like. Such products and/or applications often move large amounts of data to and from a data processor for learning, training, cognitive computing, and the like.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a block diagram of a memory according to an embodiment.

FIG. 2 is a schematic diagram of a memory according to an embodiment.

FIG. 3 is a schematic diagram of a neural network according to an embodiment.

FIG. 4 is a schematic diagram of an integrated circuit (IC) device according to an embodiment.

FIG. 5A is a circuit diagram of a monolithic 3D digital CIM DRAM bitcell according to an embodiment.

FIG. 5B is a cross-section of a device including a monolithic 3D digital CIM DRAM bitcell according to an embodiment.

FIG. 5C is a flowchart of a method of fabricating a monolithic 3D digital CIM DRAM bitcell according to an embodiment.

FIG. 6A is a circuit diagram of a heterogenous 3D digital CIM DRAM bitcell according to an embodiment.

FIG. 6B is a cross-section of a device including a heterogenous 3D digital CIM DRAM bitcell according to an embodiment.

FIG. 6C is a flowchart of a method of fabricating a monolithic 3D digital CIM DRAM bitcell according to an embodiment.

FIG. 6D is a circuit diagram of a heterogeneous 3D digital CIM DRAM bitcell according to an embodiment.

FIG. 6E is a circuit diagram of a heterogeneous 3D digital CIM DRAM bitcell according to an embodiment.

FIG. 7 is a circuit diagram of a heterogeneous 3D digital CIM DRAM bitcell according to an embodiment.

FIG. 8A is a circuit diagram of a heterogeneous 3D digital CIM DRAM bitcell according to an embodiment.

FIG. 8B is a flowchart of a method of fabricating a monolithic 3D digital CIM DRAM bitcell using active and passive substrates, according to an embodiment.

FIG. 9 is a schematic diagram of a memory macro according to an embodiment.

FIG. 10 is a flowchart of a method of operating a circuit according to an embodiment.

### DETAILED DESCRIPTION

The following disclosure provides different embodiments, or examples, for implementing features of the provided subject matter. Specific examples of components, materials, values, steps, arrangements, or the like, are described below to simplify the present disclosure. These are, of course, merely examples and are not limiting. Other components, materials, values, steps, arrangements, or the like, are contemplated. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some embodiments described herein relate to a dynamic random access memory (DRAM) bitcell implemented in a 3D structure having stacked substrates and including logic in the bitcell to perform digital computing-in-memory (CIM), which may be referred to herein as a 3D digital CIM DRAM bitcell, or a bitcell for short. Some embodiments described herein refer to a memory having a plurality of 3D digital CIM DRAM bitcells.

In at least some embodiments, computing-in-memory (or compute-in-memory) (CIM) reduces the amount of data moved to and from a processor when performing calculations using the data. In an example of a general analog CIM-static random access memory (SRAM) design, inputs/activations are transformed into analog voltage or pulsewidth.

Examples of CIM operations include mathematical operations, logical operations, combination thereof, or the like. Examples of a CIM operation include a Not Or (NOR) operation, Add Or Invert (AOI) and Or And Invert (OAI) operations, or a Multiply Accumulate (MAC) operation. Another example of a CIM operation is multiplication of a multibit weight value with a multibit input data value.

In an embodiment, the CIM operation uses, as a direct input to a CIM logic, a value stored in the bitcell. In another example, the CIM operation transfers the value stored in the bitcell to an intermediate logic or circuit, e.g., a selector or a multiplexer, which generates, as its output, an input to a CIM logic.

Examples of CIM applications, to which the embodiments disclosed herein are applicable, include artificial intelligence, image recognition, neural networks (NN) and deep neural networks (DNN) for, e.g., machine learning, large language models (LLM), Bitwise Neural Networks (BNN) in which input and output nodes and weights are represented by a single bit, or the like. In an embodiment, one or more advantages of a digital CIM include reduced data transfer, reduced processing time, reduced power consumption, reduced chip area, lowered manufacturing cost, improved performance, or the like, relative to a device or system in which computing logic receives data from memory over a bus or network.

A 3D digital CIM DRAM bitcell according to an embodiment has significant reductions in computing time and/or energy consumption relative to, e.g., a corresponding SRAM design. A 3D digital CIM DRAM bitcell according to an embodiment has a smaller footprint (area) and/or lower leakage relative to an SRAM-based digital CIM bitcell. A 3D digital CIM DRAM bitcell according to an embodiment supports applications using a large number of weight parameters.

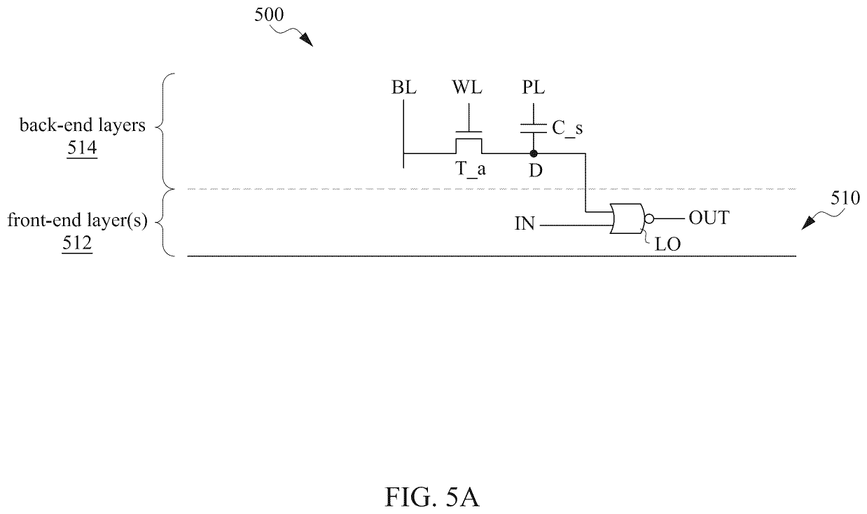

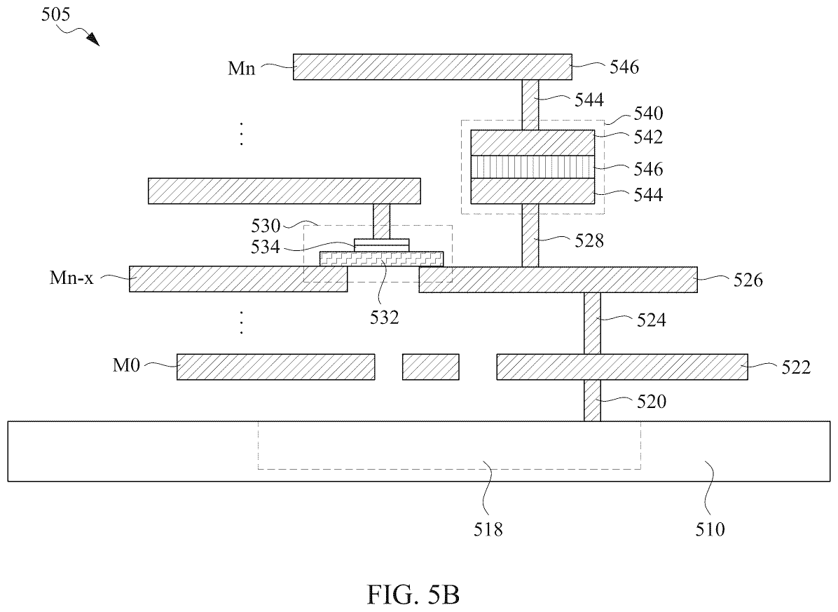

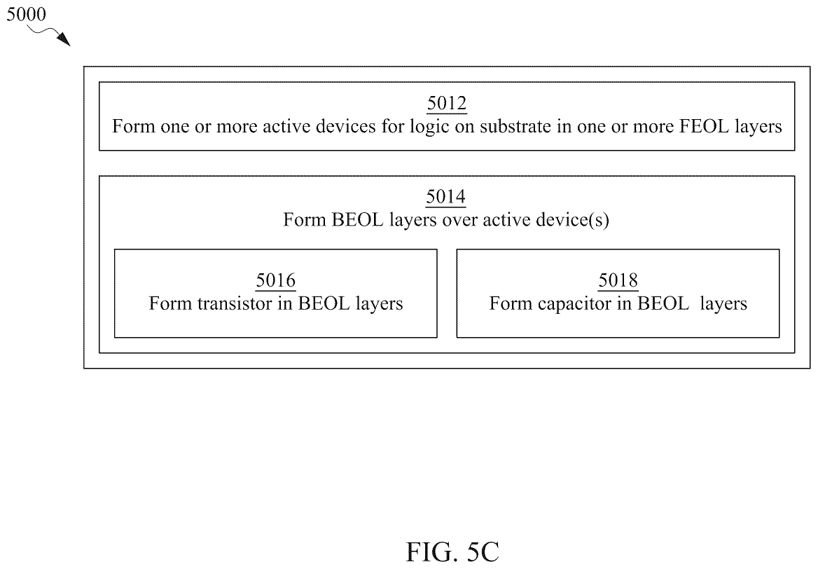

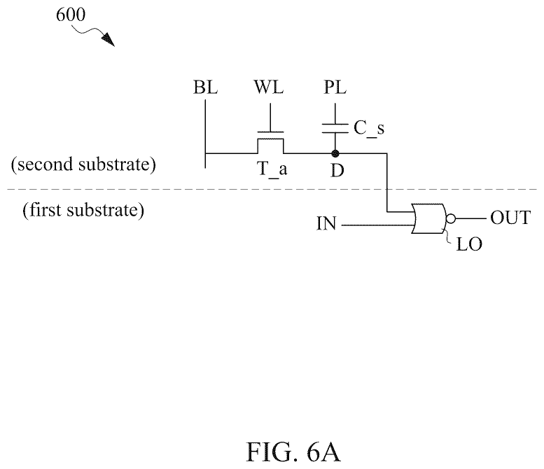

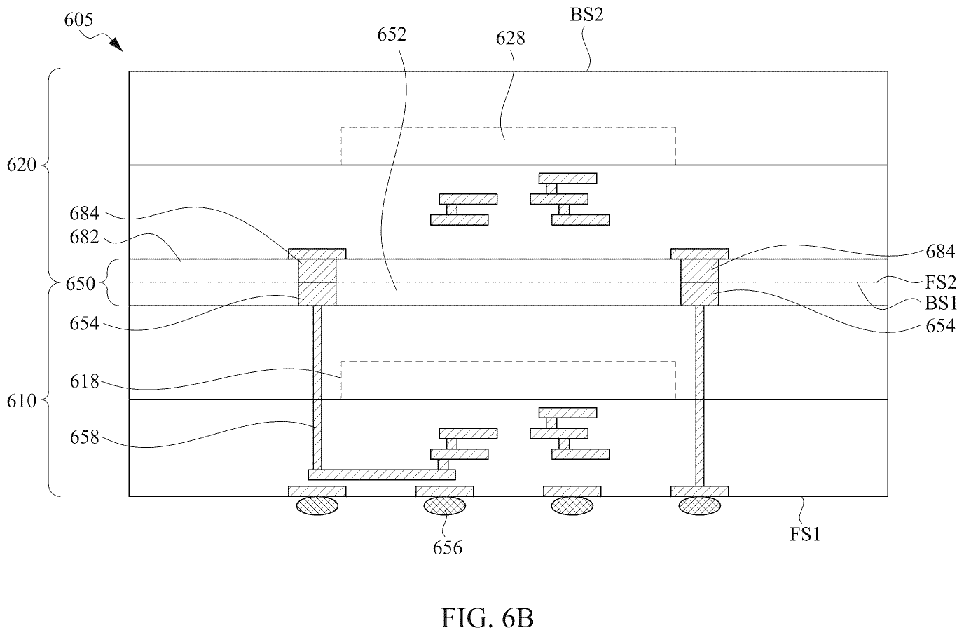

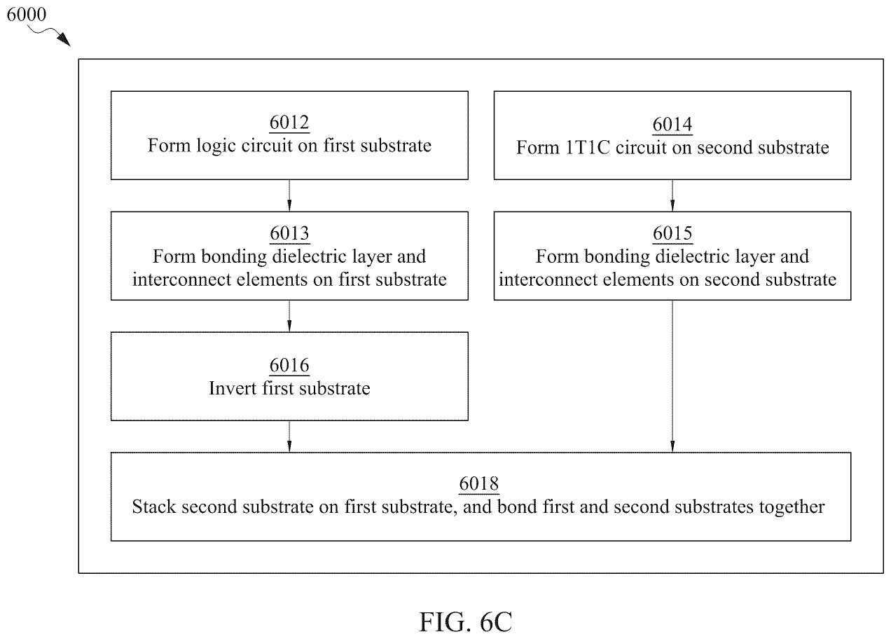

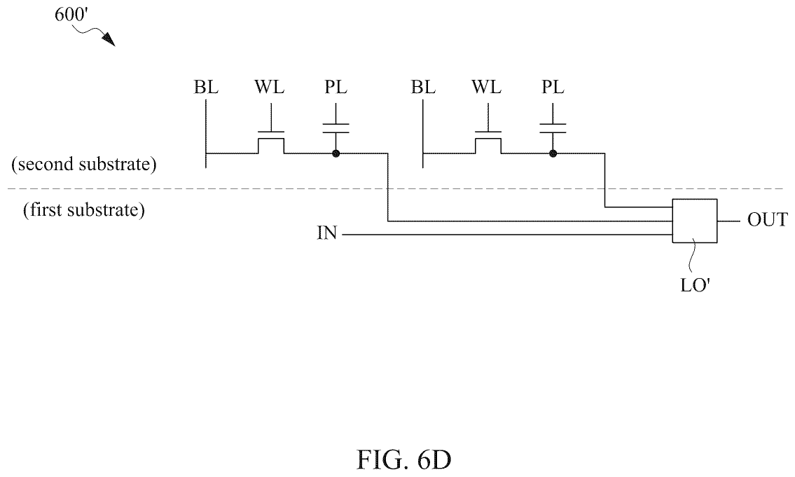

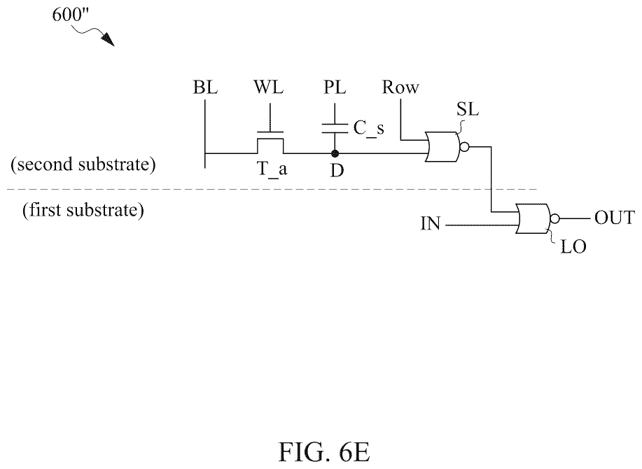

A 3D digital CIM DRAM bitcell according to an embodiment has a direct tap from a charge storage node in the back-end (BE) or front-end (FE) of a 1T1C (one transistor, one capacitor) DRAM bitcell to an input of a logic circuit or logic gate (e.g., NAND, NOR, AOI/OAI, or the like; see logic circuit LO in FIGS. 5A-8) to perform a bit-wise calculation, e.g., a weight calculation. In an embodiment, multiple sets of bitcells store different sets of weights, and a multiplexer or equivalent logic (see logic SL in FIG. 6E) switches between the different sets.

In a device according to an embodiment, logic to perform one or more logic operations (e.g., multiplication, addition, and/or other logic operations) is stacked with (e.g., placed under) the bitcell, which reduces an overall footprint or die area of the device. Such a device is also referred to as a circuit-under-array (CuA) device.

In a bitcell according to an embodiment, a CIM operation is performed without performing a bitcell readout operation using sense amplifiers, and thus reduces latency and power consumption relative to a device or system in which computing logic receives data from memory over a bus or network. In an embodiment, the bitcell supports a general read/write operation of the bitcell executed concurrently with the CIM operation.

In an embodiment, a bitcell is implemented in a 3D structure having stacked substrates in which first and second substrates are designed and/or fabricated at different technology nodes. In an embodiment, a second substrate is a memory die having an area substantially or predominantly occupied by 1T1C memory circuits. In an embodiment, the second substrate is fabricated using a process node that enables a higher voltage to be applied to wordlines on the second substrate, relative to voltages applied to gates of transistors, e.g., in logic, on a first substrate. In an embodiment, a memory circuit transistor on the second substrate is written with higher voltage than a supply voltage of logic gates on the first substrate, which helps to ensure correct function and lower leakage of the logic gates even after a retention voltage drop of the storage node of the memory cell.

In an embodiment, a memory cell array includes a plurality of memory cells, each including a memory circuit configured to store a value in a storage node. In an embodiment, each memory circuit is configured to store a digital value in the storage node. In an embodiment, each memory circuit is configured to store a 0 or a 1 as a one-bit digital value in the storage node. Herein, a memory cell that includes CIM logic and is configured to store a digital value in the storage node is referred to as a bitcell. In an embodiment, the bitcell is, and can be a 3D DRAM bitcell in which a DRAM bitcell is implemented in a 3D structure having stacked substrates. Herein, a memory cell array including a plurality of bitcells is referred to as a bitcell array.

In an embodiment, each bitcell includes a memory circuit coupled to a logic circuit. In some embodiments, a logic circuit is coupled in a one-to-one relationship with each memory circuit. In some other embodiments, a logic circuit is coupled with a plurality of memory circuits.

In an embodiment, the logic circuit is coupled to the storage node of the memory circuit. In some embodiments, the logic circuit is directly connected to the storage node of the memory circuit without an access transistor or other transistor in the connection. In some other embodiments, the storage node of the memory circuit is individually connected to (i) a corresponding access transistor and (ii) a corresponding input of a logic circuit.

In an embodiment, the logic circuit is configured to generate an output signal in response to a first signal, which represents a value stored at the storage node of the memory circuit and input to a first input of the logic circuit, and a second signal input at a second input of the logic circuit. In an embodiment, the logic circuit is configured to generate an output signal representing the result of a computing-in-memory (CIM) operation on first and second signals, where the first signal represents a value stored at the storage node of the memory circuit and input to a first input of the logic circuit, and the second signal is input at a second input of the logic circuit.

In an embodiment, each memory cell of the plurality of memory cells includes a memory circuit coupled to a logic circuit that is a multiplier circuit. In an embodiment, the logic circuit is a multiplier circuit configured to generate an output signal representing a multiplication of the first signal, which represents a value stored at the storage node of the memory circuit and input to a first input of the logic circuit, and a second signal input at a second input of the logic circuit. In an embodiment, the output signal corresponds to a product of the first signal and the second signal.

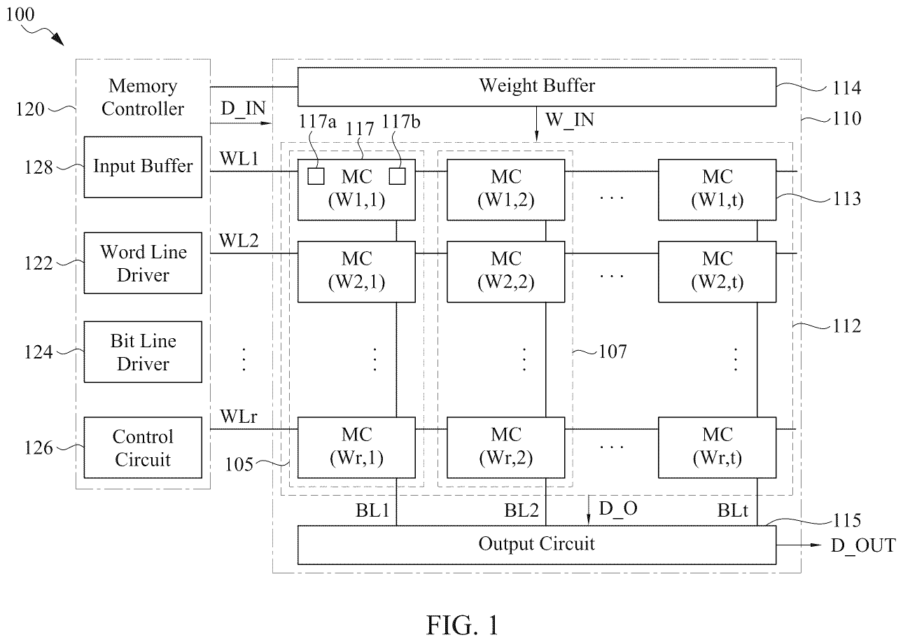

FIG. 1 is a block diagram of a memory 100 according to an embodiment.

In an embodiment, the memory 100 is implemented as an integrated circuit (IC) device. In some embodiments, the memory 100 is implemented as an individual IC device. In some other embodiments, the memory 100 is implemented as a part of a larger IC device that includes circuitry for functionalities other than those of the memory 100.

The memory 100 includes a memory macro 110 and a memory controller 120. The memory macro 110 includes a memory array 112, a weight buffer 114, and an output circuit 115. The memory controller 120 includes a word line driver 122, a bit line driver 124, a control circuit 126, and an input buffer 128. In embodiments, one or more of the word line driver 122, the bit line driver 124, the control circuit 126, or the input buffer 128 are included in the memory macro 110, and/or one or more of the weight buffer 114 or the output circuit 115 are included in the memory controller 120.

In general, a macro has a reusable configuration and is usable in various types or designs of IC devices. In an example, the macro is understood in the context of an analogy to the architectural hierarchy of modular programming in which subroutines/procedures are called by a main program (or by other subroutines) to carry out a given computational function. In this context, an IC device uses the macro to perform one or more given functions. Accordingly, in this context and in terms of architectural hierarchy, the IC device is analogous to the main program and the macro is analogous to subroutines/procedures. In an example, the macro is a soft macro. In some embodiments, the macro is a hard macro. In an example, the macro is a soft macro which is described digitally in register-transfer level (RTL) code. In an example, synthesis, placement, and routing have yet to have been performed on the macro such that the soft macro can be synthesized, placed, and routed for a variety of process nodes. In an example, the macro is a hard macro that is described digitally in a binary file format (e.g., in a Graphic Database System II (GDSII) stream format), where the binary file format represents planar geometric shapes, text labels, other information, and the like of one or more layout-diagrams of the macro in hierarchical form. In an example, synthesis, placement, and routing have been performed on the macro such that the hard macro is specific to a particular process node.

A memory macro is a macro including memory cells which are addressable to permit data to be written to or read from the memory cells. In an example, a memory macro includes circuitry configured to provide access to the memory cells and/or to perform a function, e.g., reading, writing, or another function, associated with the memory cells. In an embodiment, the memory macro 110 includes memory cells (MC) 117, as described herein, that form circuitry configured to provide a CIM function associated with the memory cells 117. The memory macro configured to provide a CIM function may be referred to as a CIM macro.

In the memory 100, the memory cells 117 of the memory macro 110 are arranged in columns and rows of the memory array 112. The memory controller 120 is electrically coupled to the memory cells 117 and configured to control operations of the memory cells 117 including, e.g., a read operation, a write operation, or the like. The memory array 112 is coupled to word lines (also referred to as “address lines”) WL1, WL2, . . . , WLr extending along the rows, and bit lines (also referred to as “data lines”) BL1, BL2, . . . , BLt extending along the columns of the memory cells 117 (where r and t are natural numbers). Various numbers of word lines and/or bit lines in the memory array 112 are within the scope of various embodiments. The word lines are commonly referred to herein as WL and the bit lines are commonly referred to herein as BL.

The memory cells 117 perform a CIM function on stored data, e.g., stored weight data, and input data. In an example embodiment, the memory 100 is configured for simultaneous weight data updating and CIM operations.

In FIG. 1, the weight buffer 114 transfers weight data W_IN to be stored in the memory cells 117, and the input buffer 128 transfers input data D_IN to the memory cells 117. In FIG. 1, the weight buffer 114 is in the memory macro 110 and the input buffer 128 is in the memory controller 120. In other embodiments, the weight buffer 114 is in the memory controller 120 and the input buffer 128 is in the memory macro 110, or the weight buffer 114 and the input buffer 128 are both in the memory macro 110, or the weight buffer 114 and the input buffer 128 are both in the memory controller 120.

Each of the memory cells 117 is electrically coupled to the memory controller 120 by at least one of the word lines WL and at least one of the bit lines BL. In some example operations, word lines WL are configured for transmitting addresses of the memory cells 117 to be read from, written to, or the like. In some example operations, bit lines BL are used for transmitting data read from or written to the memory cells 117 indicated by corresponding word lines WL.

Example memory types of the memory cells 117 include static random-access memory (SRAM), dynamic RAM (DRAM), ferroelectric RAM (FERAM), resistive RAM (RRAM), magnetoresistive RAM (MRAM), phase change RAM (PCRAM), spin transfer torque RAM (STTRAM), floating-gate metal-oxide-semiconductor field-effect transistors (FGMOS), spintronics, or the like. In an embodiment, the memory cells 117 are DRAM memory cells.

In the memory 100, the memory cells 117 are single-port memory cells. In an embodiment, a port of a memory cell is represented by a set of a word line WL and a bit line BL (referred to herein as a WL/BL set) that are configured to provide access to the memory cell in a read operation (i.e., read access) and/or in a write operation (i.e., write access). A single-port memory cell has one WL/BL set which is configured for both read access and write access, but not at the same time. In an embodiment, one or more single-port memory cells that are described herein are replaced with a corresponding multi-port memory cell. A multi-port memory cell has several WL/BL sets, each of which is configured for read access only, or for write access only, or for both read access and write access.

In an embodiment, the memory array 112 includes memory segments. A memory segment includes a memory row, a memory column, a memory bank, or the like. In an embodiment, a memory segment includes multiple memory banks. A memory row includes memory cells 117 coupled to a same word line WL. A memory column (also referred to as “memory string”) includes memory cells 117 coupled to a same bit line BL. A memory bank includes more than one memory row and/or more than one memory column. In an embodiment, a memory bank includes a section of the memory array 112 with multiple memory rows and multiple memory columns. In the memory 100, a first memory segment 105 includes a column of memory cells 117 coupled to bit line BL1. Also, a second memory segment 107 includes a column of memory cells 117 coupled to bit line BL2.

In the memory 100, each memory cell 117 includes a storage portion 117a (shown only in memory cell 117 for ease of illustration). In an embodiment, each memory cell 117 also includes a computation portion 117b (shown only in one memory cell 117 for ease of illustration).

In an embodiment, each storage portion 117a corresponds to each computation portion 117b in a one-to-one relationship. In other embodiments, one computation portion 117b corresponds to multiple storage portions 117a, e.g., a single computation portion 117b is provided as a logic element that is coupled to a plurality of the storage portions 117a using, e.g., a multiplexer or row select logic.

In an embodiment, each memory cell 117 is configured to store a bit of weight data W_IN, and to compute a corresponding bit of an output signal D_OUT1 based on a CIM operation of the bit of weight data W and a bit of input data D_IN. For example, in FIG. 1, each storage portion 117a of the memory cells 117 is configured to store a bit of the weight data W_IN, and each computation portion 117b of the memory cells 117 is configured to perform a CIM operation on the stored data and a bit of the input data D_IN. For example, the memory cell 113 (which is coupled to the word line WL1 and the bit line BLt) is configured to store a piece W1,t of the weight data W_IN, and to perform a CIM operation on the piece W1,t of the weight data W_IN and a corresponding piece of the input data D_IN. In an example embodiment, input data D_IN are serially supplied to the computation portions 117b in the form of a stream of bits.

In an embodiment, a combination of multiple pieces or bits of weight data stored in multiple memory cells constitutes a weight value to be used in a CIM operation. For simplicity, a piece or bit of weight data stored in a memory cell 117, multiple pieces or bits of weight data stored in multiple memory cells 117, or all pieces or bits of weight data stored in all memory cells 117 of the memory array 112 are referred to herein as weight data. In other embodiments, multi-bit memory cells, each of which is configured to store more than one bit of weight data and to perform a corresponding CIM operation on the corresponding multi-bit pieces of weight data, are provided.

In an embodiment, each memory cell 117 is a single-bit memory cell that stores a value of 0 or 1. In an embodiment, each memory cell 117 is a 3D digital CIM DRAM bitcell that stores a single bit.

In the memory 100, each computation portion 117b of the memory cells 117 is coupled to the input buffer 128 to receive input data D_IN, i.e., input data D_IN are supplied from the input buffer 128 in the memory controller 120. In other embodiments, the input data D_IN are received as data (e.g., output data D_OUT) output from another memory macro of the memory 100.

In the memory 100, the computation portion 117b of the memory cell 117 is configured to generate output data corresponding to a CIM operation performed on the input data D_IN (received from the input buffer 128) and the weight data W_IN stored in the memory cell 117. In an embodiment, the computation portion 117b includes, or is included in, a Not Or (NOR) circuit or an Add Or Invert (AOI) or an Or And Invert (OAI) circuit. In an embodiment, the computation portion 117b includes, or is included in, a Multiply Accumulate (MAC) circuit. Additional or different computation portions or circuits are configured to perform CIM operations other than multiplication.

In the memory 100, the weight buffer 114 is coupled to the memory array 112 and configured to temporarily hold new data, e.g., weight data, to be updated or saved in the memory array 112. In another embodiment, the weight buffer 114 is located outside of memory macro 110. In some embodiments, each memory segment is coupled to a corresponding weight buffer 114, or a common weight buffer 114 is coupled to several memory segments. The weight buffer 114 is coupled to the memory cells 117 in the memory array 112 via the bit lines BL and, in a weight data updating operation, new weight data is written into one or more memory cells 117 from the weight buffers 114 via the corresponding bit lines BL. As shown in FIG. 1, the weight buffer 114 is coupled to the memory controller 120, which controls the provision of new weight data and/or control signals that specify when and/or in which memory cells 117 the new weight data are to be updated. In an embodiment, the new weight data are received from external circuitry outside the memory 100, for example, a processor. In an example embodiment, the new weight data are received through one or more input/output (I/O) circuits (not shown) of the memory controller 120 and are forwarded to the weight buffer 114. Example weight buffers include registers, memory cells, and other circuit elements configured for data storage.

In an embodiment, the output circuit 115 is configured to latch read data from the storage portions 117a of the memory cells 117 received from the bit lines BL. In an embodiment, the output circuit 115 is or includes registers, flip-flops, latches, or the like. In an embodiment, the output circuit 115 includes sense amplifiers to read the state of a value stored in the storage portions 117a of the memory cells 117 (e.g., a logic 0 or 1).

In the memory 100, the output circuit 115 receives data D_O output from computation portions 117b of the memory cells 117. The data D_O from the computation portions 117b is supplied directly as an output signal D_OUT on an output of the output circuit 115 or is processed in the output circuit 115 and then supplied as the output signal D_OUT.

In an embodiment, the output data D_OUT are supplied, as input data, to another memory macro (not shown) of the memory 100. In an embodiment, the output data D_OUT are output, through one or more I/O circuits (not shown) of the memory controller 120, to external circuitry outside the memory 100, for example, a processor.

In the memory 100, the memory controller 120 includes the word line driver 122, the bit line driver 124, the control circuit 126, and the input buffer 128. In an embodiment, the memory controller 120 further includes one or more clock generators for providing clock signals for various components of the memory 100, one or more input/output (I/O) circuits for data exchange with external devices, and/or one or more controllers for controlling various operations in the memory 100.

In the memory 100, the word line driver 122 is coupled to the memory array 112 via the word lines WL. The word line driver 122 is configured to decode a row address of the memory cell 117 selected to be accessed in a read operation or a write operation. The word line driver 122 is configured to supply a voltage to the selected word line WL corresponding to the decoded row address, and a different voltage to the other, unselected word lines WL.

In the memory 100, the bit line driver 124 is coupled to the memory array 112 via the bit lines BL. The bit line driver 124 is configured to decode a column address of the memory cell 117 selected to be accessed in a read operation or a write operation. The bit line driver 124 is configured to supply a voltage to the selected bit line BL corresponding to the decoded column address, and a different voltage to the other, unselected bit lines BL.

In the memory 100, the control circuit 126 is coupled to one or more of the memory cells 117, the weight buffer 114, the output circuit 115, the word line driver 122, the bit line driver 124, or the input buffer 128 to coordinate operations of these circuits, drivers, and/or buffers in the overall operation of the memory 100. For example, the control circuit 126 is configured to generate various control signals for controlling operations of one or more of the memory cells 117, the weight buffer 114, the output circuit 115, the word line driver 122, the bit line driver 124, and/or the input buffer 128.

In the memory 100, the input buffer 128 is configured to receive the input data from external circuitry outside the memory 100, for example, a processor. The input data are received through one or more I/O circuits (not shown) of the memory controller 120 and are forwarded via the input buffer 128 to the memory array 112. Example input buffers include registers, memory cells, or other circuit elements configured for data storage.

The memory 100 including a plurality of 3D digital CIM DRAM bitcells is advantageous relative to another approach where data are moved back and forth between the memory and a processor to provide computations, because such back-and-forth data movement, which is a bottleneck to both performance and energy efficiency, is avoidable using the memory 100.

As described above, in an embodiment, each memory cell 117 includes a storage portion 117a and a computation portion 117b, each storage portion 117a is configured to store a piece or a bit of weight data W_IN, and each computation portion 117b is configured to perform a CIM operation on the piece or bit of weight data W_IN and a piece of received data D_IN.

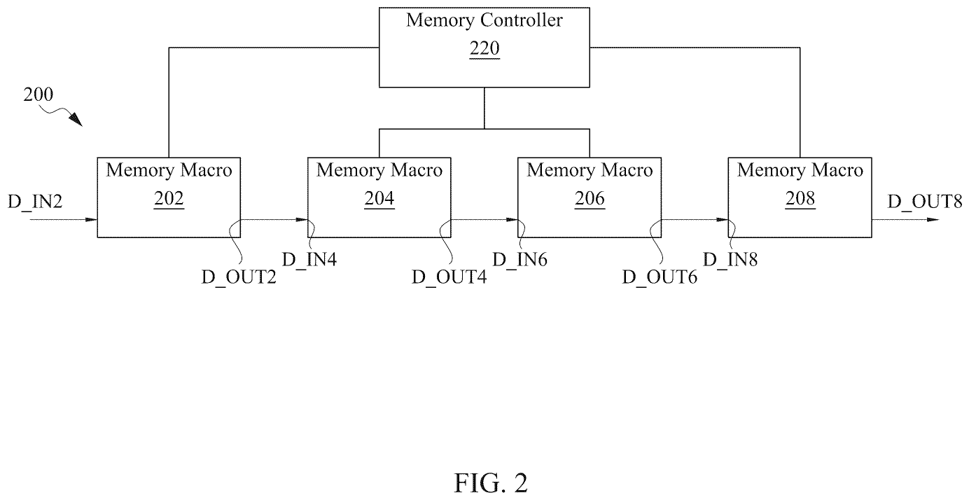

FIG. 2 is a schematic diagram of a memory 200 according to an embodiment.

The memory 200 includes memory macros 202, 204, 206, and 208, and a memory controller 220. In an embodiment, one or more of the memory macros 202, 204, 206, and 208 corresponds to the memory macro 110 of FIG. 1. In an embodiment, the memory controller 220 corresponds to the memory controller 120 of FIG. 1.

The memory controller 220 is a common memory controller for the memory macros 202, 204, 206, and 208. In another embodiment, at least one of the memory macros 202, 204, 206, and 208 has its own memory controller. In FIG. 2 as an example, the number of memory macros in the memory 200 is four.

In the memory 200, the memory macros 202, 204, 206, and 208 are coupled to each other in sequence, with output data of a preceding memory macro being input data for a subsequent memory macro. For example, input data D_IN2 are input to the memory macro 202. The memory macro 202 performs one or more CIM operations based on the input data D_IN2 and weight data (as described in connection with FIG. 1) stored in the memory macro 202, and generates output data D_OUT2 as results of the CIM operations. The output data D_OUT2 are supplied as input data D_IN4 to the memory macro 204. The memory macro 204 performs one or more CIM operations based on the input data D_IN4 and weight data stored in the memory macro 204, and generates output data D_OUT4 as results of the CIM operations. The output data D_OUT4 are supplied as input data D_IN6 of the memory macro 206. The memory macro 206 performs one or more CIM operations based on the input data D_IN6 and weight data stored in the memory macro 206, and generates output data D_OUT6 as results of the CIM operations. The output data D_OUT6 are supplied as input data D_IN8 of the memory macro 208. The memory macro 208 performs one or more CIM operations based on the input data D_IN8 and weight data stored in the memory macro 208, and generates output data D_OUT8 as results of the CIM operations. In an embodiment, one or more of the input data D_IN2, D_IN4, D_IN6, and D_IN8 correspond to the input data D_IN described with respect to FIG. 1, and/or one or more of the output data D_OUT2, D_OUT4, D_OUT6, and D_OUT8 corresponds to the output data D_OUT described with respect to FIG. 1. In an embodiment, the configuration of the memory macros 202, 204, 206, and 208 is implemented as, or as part of, a neural network.

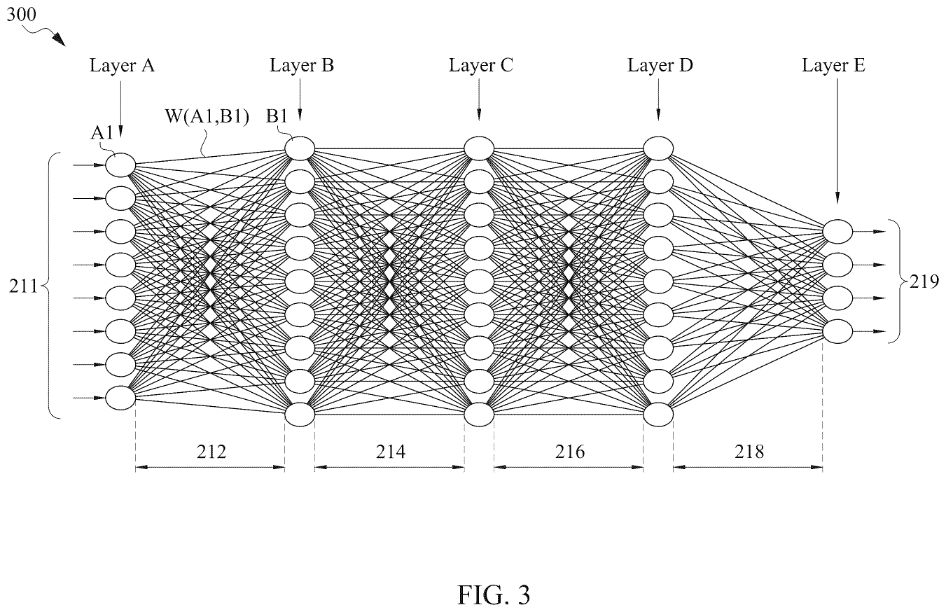

FIG. 3 is a schematic diagram of a neural network 300 according to an embodiment.

The neural network 300 includes layers A, B, C, D, and E, each including a plurality of nodes (or neurons). The nodes in successive layers of the neural network 300 are connected with each other by a matrix or array of connections. For example, the nodes in layers A and B are connected with each other by connections in a matrix 212, the nodes in layers B and C are connected with each other by connections in a matrix 214, the nodes in layers C and D are connected with each other by connections in a matrix 216, and the nodes in layers D and E are connected with each other by connections in a matrix 218. Layer A is an input layer configured to receive input data 211. The input data 211 propagate through the neural network 300, from one layer to the next layer via the corresponding matrix of connections between the layers. As the data propagate through the neural network 300, the data undergo one or more computations, and are output as output data 219 from layer E, which is an output layer of the neural network 300. The three layers B, C, and D between the input layer A and the output layer E are referred to as hidden layers or intermediate layers. FIG. 3 shows three hidden layers. In some embodiments, the neural network 300 has one, two, or more than three hidden or intermediate layers. The number of layers, the number of matrices of connections, and the number of nodes in each layer in FIG. 3 are examples. In another embodiment, the neural network 300 includes no hidden layer, and has an input layer connected by one matrix of connections to an output layer.

In an embodiment, the matrices 212, 214, 216, and 218 are correspondingly implemented by the memory macros 202, 204, 206, and 208, the input data 211 correspond to the input data D_IN2, and the output data 219 correspond to the output data D_OUT8, and similar detailed description is therefore omitted. In an embodiment, in the matrix 212, a connection between a node in layer A and another node in layer B has a corresponding weight. For example, a connection between node A1 and node B1 has a weight W(A1,B1) which corresponds to a weight value stored in the memory array of the memory macro 202. The memory macros 204, 206, and 208 are configured in a similar manner. The weight data in one or more of the memory macros 202, 204, and 206, and 208 are updated, e.g., by a processor and through the memory controller 220, as machine learning is performed using the neural network 300. One or more advantages described herein are achievable in the neural network 300 implemented in whole or in part by one or more memories, memory macros, and/or memory devices in accordance with some embodiments.

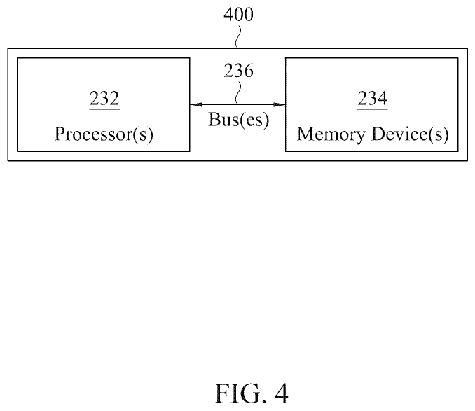

FIG. 4 is a schematic diagram of an integrated circuit (IC) device 400 according to an embodiment.

In an example embodiment, the IC device 400 includes the memory 100 of FIG. 1. In an example embodiment, the IC device 400 includes the memory 200 of FIG. 2.

The IC device 400 includes one or more processors 232, and one or more memory devices 234 coupled to the one or more processors 232 by one or more buses 236. In an embodiment, the one or more processors 232 are each hardware processors. In an embodiment, the one or more processors 232 is useable as one or more components in memory controller 120 of FIG. 1 or memory controller 220 in FIG. 2. In an embodiment, the one memory device 234 is useable as one or more components in memory macro 110 of FIG. 1, or one or more of memory macros 202, 204, 206, or 208 in FIG. 2.

In an embodiment, the IC device 400 includes one or more additional circuits such as a cellular transceiver, a global positioning system (GPS) receiver, network interface circuitry for one or more of Wi-Fi, USB, or Bluetooth, and the like. Examples of the processor 232 include a central processing unit (CPU), a multi-core CPU, a neural processing unit (NPU), a graphics processing unit (GPU), a digital signal processor (DSP), a field-programmable gate array (FPGA), an application-specific integrated circuit (ASIC), other programmable logic devices, a multimedia processor, an image signal processor (ISP), or the like. Examples of the memory device 234 include one or more memories, memory devices, and/or memory macros as described herein. In an embodiment, each of multiple processors 232 is coupled to a corresponding memory device among multiple memory devices 234.

In an embodiment, one or more of the memory devices 234 are CIM memory devices including a plurality of 3D digital CIM DRAM bitcells as described herein and, as such, various computations can be performed in the memory devices. This reduces the computing workload of the corresponding processor(s) 232, reduces data transmission (e.g., on the bus(es) 236), reduces memory access time, and/or improves performance relative to a device or system in which computing logic receives data from memory over a bus or network. In an embodiment, the IC device 400 is a system-on-a-chip (SOC).

FIG. 5A is a circuit diagram of a monolithic 3D digital CIM DRAM bitcell 500 according to an embodiment.

In an embodiment, the bitcell 500 is included in or is the memory cell 117 described in connection with FIG. 1.

In an embodiment, the bitcell 500 is implemented as a monolithic 3D device having front-end devices formed in front-end layer(s) 512 on a first side of a substrate 510, and having back-end devices formed in back-end layers 514 on the first side of the substrate 510, over the front-end layer(s) 512. In some embodiments, the front-end devices and/or the back-end devices are active devices that include at least one transistor. The substrate 510 can be a wafer, die, or other substrate.

In the bitcell 500, the back-end layers 514 include a memory circuit having a 1T1C design (i.e., a 1T1C circuit). Memory structures other than a 1T1C circuit are usable.

In the bitcell 500, a storage node D is in the back-end layers 514, and the storage node D is electrically connected to a logic circuit LO that includes transistors in the front-end layer(s) 512. In FIG. 5A, the bitcell 500 is implemented with a 1T1C circuit, an access transistor T_a and a storage capacitor C_s of the 1T1C circuit are both in the back-end layers 514, and an electrical connection extends from the storage node D (which is connected to a terminal of the storage capacitor C_s) in the back-end layers 514 to the transistors of the logic circuit LO in the front-end layer(s) 512.

The front-end layer(s) 512 include transistors forming a NOR gate (as an example of the logic circuit LO) having, at a first input, the electrical connection to the storage node D in the back-end layers 514. That is, an input to the NOR gate is a first signal representing the value stored in the storage node D. The NOR gate receives, at a second input, an input signal IN that is logically combined with the first signal (representing the value, e.g., logic 0 or 1 stored in the storage node D), and the NOR gate operates to output an output signal OUT that is ‘false’ if either input is ‘true’. In another embodiment (not shown in FIG. 5A; see FIG. 6D), the logic circuit LO has three or more inputs, one of which is the first signal representing the value stored in the storage node D. In other embodiments, the logic circuit LO is logic (which can be one circuit stage or a plurality of circuit stages) configured to perform an operation such as AOI or OAI, or a selection or multiplexing operation, in each case the logic circuit LO receiving the first signal representing the value stored in the storage node D as an input. In an embodiment, the bitcell 500 constitutes a bitwise multiplier.

In an embodiment, the bitcell 500 is written with a voltage corresponding to a weight value to be stored in the storage node D. In an embodiment, a plurality of bitcells 500 is provided and each bitcell 500 stores a bit of a multibit weight value.

In FIG. 5A, the storage node D has three connections: the connection to the logic circuit LO, a connection to the access transistor T_a of the 1T1C circuit, and a connection to the storage capacitor C_s. In the bitcell 500, a transistor is on only one of the three connections, the transistor being the access transistor T_a. The first signal representing the value stored in the storage node D is transferred to logic circuit LO without being actively controlled, gated, or switched. In other words, the connection from the storage node D in the back-end layers 514 to the input of the logic circuit LO is free of a transistor, and the logic circuit LO directly taps the storage node D.

Examples of the access transistor T_a include metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), finFETs, planar MOS transistors with raised source/drains, or the like.

In the bitcell 500, a wordline (WL) is connected to a gate of the access transistor T_a and a bitline (BL) is connected to a source/drain region (e.g., the source region) of the access transistor T_a.

The storage capacitor C_s has a terminal connected to the storage node D. In an embodiment, the storage capacitor C_s is a discrete device, e.g., having first and second terminals separated by a charge storage dielectric, e.g., a dielectric layer such as a high-k material layer. In another embodiment, a capacitive structure other than a discrete capacitor is used. In an embodiment, the storage node D is part of or connected to the drain of the access transistor T_a.

Herein, the access transistor T_a is considered to be activated in response to a voltage on the wordline WL being sufficient to place the access transistor T_a in a conductive state. In an embodiment, the access transistor T_a is activated in order to write a value to, or read a value from, the storage node D, whereas the connection between the storage node D and the input of the logic circuit LO on the first substrate remains connected regardless of the voltage on the wordline WL or the state of the access transistor T_a.

In FIG. 5, the storage node D is coupled to or formed as a terminal of the storage capacitor C_s. In other embodiments, the storage node D is a storage element of an SRAM, an FERAM, an RRAM, an MRAM, a PCRAM, an STTRAM, a FGMOS, a spintronic element or the like, that remains connected to the input of the logic circuit LO without being actively controlled, gated, or switched.

In an embodiment, the back-end layers 514 include the bitcell 500 in plural and arranged in an array, e.g., a regular rectangular grid pattern. The array of bitcells 500 may be referred to herein as a bitcell array. In an embodiment of the bitcell array, two or more DRAM cells in a column share a single bitline BL.

In the bitcell 500, the storage node D is coupled to or formed as a terminal of the storage capacitor C_s. The storage capacitor C_s has a first terminal connected to the storage node D and a second terminal connected to a plate line PL. In an embodiment, respective plate lines PL of a plurality of bitcells 500 are electrically connected in common. In an embodiment, the plate line PL is held to a reference voltage, e.g., ground (GND) or VSS, although another voltage, e.g., VDD, is used in other embodiments. In an embodiment, the reference voltage is a constant voltage. In another embodiment, the reference voltage is modulated or controlled to vary. In an embodiment, the storage element is an FERAM and the reference voltage is VDD which is pulsed to a voltage other than VDD in an operation of writing to the storage element.

in FIG. 5A, the access transistor T_a and the storage capacitor C_s are fabricated as BEOL devices in the back-end layers 514, and the logic circuit LO includes one or more transistors fabricated as FEOL devices in the front-end layer(s) 512. Fabricating at least one of the access transistor T_a or the storage capacitor C_s as a BEOL device in the back-end layers 514 reduces an overall area of bitcell 500. In an embodiment, transistors implemented as BEOL devices, i.e., integrated into metal levels of the back-end layers 514, are thin film transistors (TFTs). In an example embodiment, transistors implemented as BEOL devices include an oxide semiconductor material such as Indium-Gallium-Zinc oxide (IGZO) for the semiconductor layer (or channel). The bitcell 500 in FIG. 5A includes an NMOS transistor as the access transistor T_a but in other embodiments the access transistor T_a is a PMOS transistor.

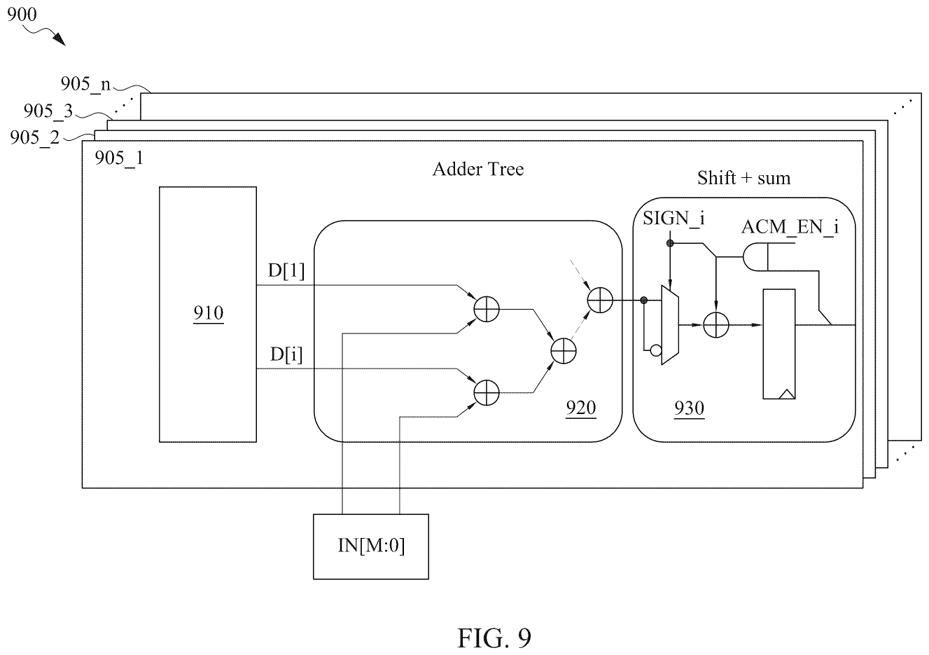

As described in further detail below in connection with FIG. 9, the output signal OUT of the logic circuit LO of the bitcell 500 can be provided as an input to an adder tree.

In FIG. 5A, the access transistor T_a is included in the back-end layers 514. In other embodiments, the access transistor T_a is included in the front-end layer(s) 512.

FIG. 5B is a cross-section of a device 505 including a monolithic 3D digital CIM DRAM bitcell according to an embodiment.

In FIG. 5B, the bitcell device 505 includes one or more active devices formed in an active region 518 of a semiconductor substrate 510. In some embodiments, the active devices formed in the active region 518 include one or more transistors, which in some examples are MOSFETs, PFETs and/or NFETs, CMOS transistors, finFETs, planar MOS transistors with raised source/drains, BJTs, high voltage transistors, high frequency transistors, or the like. The active devices form parts of a logic circuit LO in FEOL layer(s). In some embodiments, the active devices form parts of one or more logic gates of a logic circuit such as a NAND, NOR, AOI/OAI, or the like.

In the bitcell device 505, BEOL layers over the substrate 510 include metal layers M0˜Mn. A first metal layer M0 includes a conductor 522 connected to an active device in the active region 518 by a contact 520. The conductor 522 is connected to a conductor 526 in an overlying metal layer Mn-x by a via 524.

An access transistor 530 of a 1T1C DRAM memory circuit is formed over the metal layer Mn-x. The access transistor 530 includes a semiconductor layer 532 and a gate 534. The semiconductor layer 532 is a channel layer of the access transistor 520, and has source/drain regions on opposite sides of the gate 534. In an embodiment, the semiconductor layer 532 includes an oxide semiconductor material such as IGZO. The access transistor 530 includes a gate dielectric layer (not shown) between the semiconductor layer 530 and the gate 534. In an embodiment, the gate dielectric layer is formed of a metal oxide material. In an embodiment, the gate 534 is formed of a metal or other conductive material generally used for metal lines in the metal layers M0˜Mn. In another embodiment, the gate 534 is formed of a material selectively used for the gate 534 and different from a metal used in the metal layers M0˜Mn.

A storage capacitor 540 is formed in the BEOL layers over the access transistor 530. The storage capacitor 540 is connected to the access transistor 530 by a via 528 and the conductor 526. The storage capacitor 540 includes first and second capacitor electrodes 542, 544 facing a capacitor dielectric layer 546. In an embodiment, the first capacitor electrode 542 is formed in one of the metal layers M0˜Mn and the second capacitor electrode 544 is formed as another conductive layer over the capacitor dielectric layer 546. The second capacitor electrode 542 is connected to a conductor 546 by a via 544. In an embodiment, the capacitor electrodes 542, 544 are formed of a metal or other conductive material generally used for metal lines in the metal layers M0˜Mn. In another embodiment, the capacitor electrodes are formed of a material selectively used for the capacitor electrodes and different from a metal used in the metal layers M0˜Mn. In an embodiment, the capacitor dielectric layer 546 is formed of a material selectively used for the capacitor dielectric material and different from a material of dielectric layers that separate the metal layers M0˜Mn. In an embodiment, the capacitor dielectric layer 546 is a high-k material layer.

FIG. 5C is a flowchart of a method 5000 of fabricating a monolithic 3D digital CIM DRAM bitcell according to an embodiment.

The method 5000 includes an operation 5012 of forming one or more active devices in one or more FEOL layers on a first side of a substrate. In some embodiments, the substrate is a wafer, die, or other substrate. In some embodiments, the substrate is a single-crystal silicon substrate, a substrate having a silicon-on-insulator (SOI) structure, or another type of semiconductor substrate. In some embodiments, the active devices include one or more transistors, which in some examples are MOSFETs, PFETs and/or NFETs, CMOS transistors, finFETs, planar MOS transistors with raised source/drains, BJTs, high voltage transistors, high frequency transistors, or the like. The active devices form parts of a logic circuit LO in the FEOL layer(s). In some embodiments, the active devices in the FEOL layer(s) form parts of one or more logic gates such as a NAND, NOR, AOI/OAI, or the like.

The method 5000 includes an operation 5014 of forming BEOL layers on the first side of the substrate, over the FEOL layer(s). The forming of the BEOL layers includes forming one or more metal layers M0˜Mn, forming interlayer dielectrics, and forming interconnecting vias. The metal layers M0˜Mn and the vias in the BEOL layers form wiring that interconnects active devices in the FEOL layer(s) to complete the one or more logic gates (e.g., NAND, NOR, AOI/OAI, or the like), and connect the access transistor T_a, the storage capacitor C_s, and storage node D in the BEOL layers.

The operation 5014 includes operation 5016 of forming the access transistor T_a in the BEOL layers and operation 5018 of forming the storage capacitor C_s in the BEOL layers.

The operation 5016 of forming the access transistor T_a in the BEOL layers includes forming a semiconductor layer and forming a gate adjacent to the semiconductor layer. The semiconductor layer is formed to serve as a channel layer, and has source/drain regions on opposite sides of the gate. In an embodiment, the semiconductor layer is an oxide semiconductor, e.g., IGZO. Forming the access transistor T_a in the BEOL layers further includes forming a gate dielectric layer between the semiconductor layer and the gate. In an embodiment, the gate dielectric layer is formed of a metal oxide material. In an embodiment, the gate is formed of a metal or other conductive material generally used for metal lines in the metal layers M0˜Mn. In another embodiment, the gate is formed of a material selectively used for the gate and different from the material of the metal lines. In an embodiment, the access transistor T_a is formed as a planar FET.

The operation 5018 of forming the storage capacitor C_s in the BEOL layers includes forming capacitor electrodes facing a capacitor dielectric layer. In an example, a first capacitor electrode is formed in one of the metal layers M0˜Mn and a second capacitor electrode is formed in another, adjacent one of the metal layers M0˜Mn. In an embodiment, the capacitor electrodes are formed of a metal or other conductive material generally used for metal lines in the metal layers M0˜Mn. In another embodiment, the capacitor electrodes are formed of a material selectively used for the capacitor electrodes and different from the material of the metal lines. In an embodiment, the capacitor dielectric layer is formed of a material selectively used for the capacitor dielectric material and different from a material of the interlayer dielectric layers of the BEOL layers.

In some embodiments, the access transistor T_a is formed in lower layers of the BEOL layers and the storage capacitor C_s is formed in higher layers of the BEOL layers, over the access transistor. In other embodiments, the storage capacitor C_s is formed in BEOL layers that are common to the access transistor T_a, or is formed under the access transistor T_a. In some embodiments, the access transistor T_a and/or the storage capacitor C_s are formed to vertically overlap the logic gate(s) in the FEOL layer(s), thus reducing a die area occupied by the monolithic 3D digital CIM DRAM bitcell.

In the method 5000, the access transistor T_a is described as being formed in the front-end layer(s) 512. In other embodiments, the access transistor T_a is formed in the back-end layers 514 instead.

FIG. 6A is a circuit diagram of a heterogenous 3D digital CIM DRAM bitcell 600 according to an embodiment.

In an embodiment, the bitcell 600 is included in or is the memory cell 117 described in connection with FIG. 1.

The bitcell 600 has a stack of substrates in which a first substrate and a second substrate are combined by being stacked, one over the other.

In an embodiment, the bitcell 600 is a heterogenous device in which the first and second substrates are different dies, have different functionalities, and/or are fabricated using different wafer node technologies (i.e., different process nodes).

For ease of reference, the first substrate may be referred to as a lower or bottom substrate, and the second substrate may be referred to as an upper or top substrate, but the terms “lower,” “bottom,” “upper,” and “top” do not imply a particular orientation.

Although FIG. 6A illustrates certain elements as being included in the first or lower substrate, such elements can be included in the second or upper substrate instead. In other embodiments, elements that are illustrated as being included in the second or upper substrate are included in the first or lower substrate instead.

The first substrate can be a wafer, die, or other substrate. The second substrate can be a wafer, die, or other substrate. The first substrate can be the same type as, or a different type from, the second substrate. The second substrate can be a die and the first substrate can be a wafer, which structure may be referred to as a die-on-wafer or chip-on-wafer (CoW) structure. The second substrate can be a first wafer and the first substrate can be a second wafer, which structure may be referred to as a wafer-on-wafer (WoW) structure. The first and second substrates can be combined in a face-to-face arrangement or a face-to-back arrangement.

In another embodiment, the first and second substrates include elements, e.g., active or passive elements such as transistors or capacitors, that are fabricated in accordance with a same process node for each of the first and second substrates. In another embodiment, the first substrate includes elements, e.g., active or passive elements such as transistors or capacitors, that are fabricated in accordance with a first process node, and the second substrate includes elements, e.g., active or passive elements such as transistors or capacitors, that are fabricated in accordance with a second process node that is different from the first process node. In the case that the second process node is different from the first process node, the second process node can correspond to a different cost and/or PPA (power, performance, and area) of a fabricated element relative to the first process node. In a specific example, in the case that the second process node is different from the first process node, the second process node provides a minimum transistor gate length different from that of the first process node.

In some embodiments, the first and second substrates are the only substrates in the stack, i.e., the stack of substrates has exactly two substrates, or in other embodiments the first and second substrates are two substrates in a stack of three or more substrates. Increasing the number of substrates in the stack increases overall memory density.

The first and second substrates are combined using a suitable 3D stacking technology. In some embodiments, the first and second substrates are combined using a hybrid bonding or bumpless technology such as SoIC-X, a microbump technology such as SoIC-P, or the like. SoIC refers to System on Integrated Chips, which provides for logic-on-logic and memory-on-logic chip stacking, as well as heterogeneous integration of dies of different sizes, different functionalities, and/or different wafer node technologies (i.e., different process nodes), all integrated in a single, compact system chip.

In an embodiment using the hybrid bonding or bumpless technology, the first and second substrates are combined using hybrid bonding in which two materials are bonded (e.g., (first material) metal-to-metal bonding such as copper-to-copper bonding, and (second material) dielectric-to-dielectric bonding) or more than two materials are bonded. The metal-to-metal bonding forms interconnects in which metal features (e.g., metal lines, metal pads, or the like) at a surface of the first substrate are bonded to metal features (e.g., metal lines, metal pads, or the like) at a surface of the second substrate. SoIC-X is a bumpless stacking technology using hybrid bonding that can be used for die-on-wafer or chip-on-wafer stacking with bond pitches of about 4.5 μm to about 9 μm.

In an embodiment using the microbump technology, the first and second substrates are combined using microbumps in which metal (e.g., solder or the like) microbumps at the surface of one of the first or second substrates are bonded to metal features (e.g., metal lines, metal pads, or the like) at the surface of the other of the first or second substrates. The microbump technology forms interconnects that include the microbumps. SoIC-P is a microbump (μbump) stacking technology usable for about 18 μm to about 25 μm pitch μbump stacking. In the case that three or more substrates are stacked, a same stacking technology is used for all of the substrates or a mixture of stacking technologies is used.

In the bitcell 600, the second substrate includes a memory circuit having a 1T1C design (i.e., a 1T1C circuit). Memory structures other than a 1T1C circuit are usable.

In the bitcell 600, a storage node D is on the second substrate, and the storage node D is electrically connected to a logic circuit LO on the first substrate. In FIG. 6A, the bitcell 600 is implemented with a 1T1C circuit, an access transistor T_a and a storage capacitor C_s of the 1T1C circuit are both on the second substrate, and the electrical connection extends from the storage node D (e.g., from a terminal of the storage capacitor) on the second substrate to the logic circuit LO on the first substrate. The electrical connection is, or includes, an interconnect formed using hybrid bonding or bumpless technology, an interconnect formed using a microbump technology, or the like, as described above.

In the bitcell 600, the first substrate includes a NOR gate (as an example of the logic circuit LO) having, at a first input, the electrical connection to the storage node D on the second substrate. That is, an input to the NOR gate is a first signal representing the value stored in the storage node D. The NOR gate receives, at a second input, an input signal IN that is logically combined with a first signal representing the value (e.g., logic 0 or 1) stored in the storage node D, and the NOR gate operates to output an output signal OUT that is ‘false’ if either input is ‘true’. In another embodiment (not shown in FIG. 6A; see FIG. 6B), the logic circuit LO has three or more inputs, one of which is the first signal representing the value stored in the storage node D. In other embodiments, the logic circuit LO is logic (which can be one circuit stage or a plurality of circuit stages) configured to perform an operation such as AOI or OAI, or a selection or multiplexing operation, in each case the logic circuit LO having the first signal representing the value stored in the storage node D as an input. In an embodiment, the bitcell 600 constitutes a bitwise multiplier.

In an embodiment, the bitcell 600 is written with a voltage corresponding to a weight value to be stored in the storage node D. In an embodiment, a plurality of bitcells 600 is provided and each bitcell 600 stores a bit of a multibit weight value.

In FIG. 6A, the storage node D has three connections: the connection to the logic circuit LO on the first substrate, a connection to the access transistor T_a of the 1T1C circuit, and a connection to the storage capacitor C_s. In the bitcell 600, a transistor is on only one of the three connections, the transistor being the access transistor T_a. The first signal representing the value stored in the storage node D is transferred to logic circuit LO without being actively controlled, gated, or switched. In other words, the connection from the storage node D on the second substrate to the input of the logic circuit LO on the first substrate is free of a transistor, and the logic circuit LO directly taps the storage node D.

Examples of the access transistor T_a include metal oxide semiconductor field effect transistors (MOSFET), complementary metal oxide semiconductor (CMOS) transistors, bipolar junction transistors (BJT), high voltage transistors, high frequency transistors, p-channel and/or n-channel field effect transistors (PFETs/NFETs), finFETs, planar MOS transistors with raised source/drains, or the like.

In the bitcell 600, a wordline (WL) is connected to a gate of the access transistor T_a and a bitline (BL) is connected to a source/drain region (e.g., the source region) of the access transistor T_a.

In FIG. 6A, the storage capacitor C_s has a terminal connected to the storage node D. In an embodiment, the storage capacitor C_s is a discrete device, e.g., having first and second terminals separated by a charge storage dielectric, e.g., a dielectric layer. In another embodiment, a capacitive structure other than a discrete capacitor is used. In an embodiment, the storage node D is part of or connected to the drain of the access transistor T_a.

Herein, the access transistor T_a is considered to be activated in response to a voltage on the wordline WL being sufficient to place the access transistor T_a in a conductive state. In an embodiment, the access transistor T_a is activated in order to write a value to, or read a value from, the storage node D, whereas the connection between the storage node D and the input of the logic circuit LO on the first substrate remains connected regardless of the voltage on the wordline WL or the state of the access transistor T_a.

In other embodiments, the storage node D is a storage element of an SRAM, an FERAM, an RRAM, an MRAM, a PCRAM, an STTRAM, a FGMOS, a spintronic element or the like, that remains connected to the input of the logic circuit LO without being actively controlled, gated, or switched.

In an embodiment, the second substrate includes the bitcell 600 in plural and arranged in an array, e.g., a regular rectangular grid pattern. The array of bitcells 600 may be referred to herein as a bitcell array. In an embodiment of the bitcell array, two or more DRAM cells in a column share a single bitline BL.

In the bitcell 600, the storage node D has a connection to the storage capacitor C_s. The storage capacitor C_s has a first terminal connected to the storage node D and a second terminal connected to a plate line PL. In an embodiment, respective plate lines PL of a plurality of bitcells 600 are electrically connected in common. In an embodiment, the plate line PL is held to a reference voltage, e.g., ground (GND) or VSS, although another voltage, e.g., VDD, is used in other embodiments. In an embodiment, the reference voltage is a constant voltage. In another embodiment, the reference voltage is modulated or controlled to vary. In an embodiment, the storage element is an FERAM and the reference voltage is VDD which is pulsed to a voltage other than VDD in an operation of writing to the storage element.

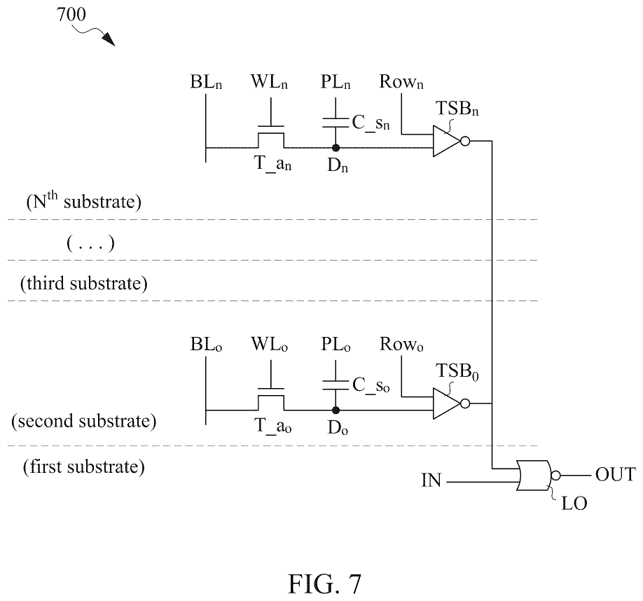

In an embodiment, a memory includes an array of bitcells 600, each bitcell 600 having a storage node D on the second substrate and an electrical connection (which is, or includes, a hybrid bonding or bumpless interconnect, a microbump interconnect, or the like), such that an array of electrical connections (i.e., an array of hybrid bonding or bumpless interconnects, microbump interconnects, or the like) corresponding to the array of bitcells 600 connect the first and second substrates. In an example embodiment, a ratio of bitcells: first-to-second substrate electrical connections is 1:1 in the array. In another example embodiment, the ratio of bitcells: first-to-second substrate electrical connections is other than 1:1. For example, the bitcell 700 of FIG. 7, discussed below, includes a 2:1 ratio (or higher) of bitcells: first-to-second substrate electrical connections, i.e., 2 or more bitcells share an electrical connection between substrates.

In an embodiment, the bitcell 600 includes the access transistor T_a fabricated as a FEOL device on the second substrate, and the logic circuit LO includes one or more transistors fabricated as FEOL devices on the first substrate. In an embodiment, the access transistor T_a and the storage capacitor C_s are fabricated as FEOL devices on the second substrate, and the logic circuit LO includes one or more transistors fabricated as FEOL devices on the first substrate. In an embodiment, at least one of the access transistor T_a or the storage capacitor C_s is fabricated as a BEOL device on the second substrate (e.g., in metal layers over FEOL devices on the second substrate, which reduces an overall area of the second substrate), and the logic circuit LO includes one or more transistors fabricated as FEOL devices on the first substrate. In an example embodiment, transistors implemented as BEOL devices, i.e., integrated into metal levels of the BEOL structure, are thin film transistors (TFTs). In an example embodiment, transistors implemented as BEOL devices include an Indium-Gallium-Zinc oxide (IGZO) channel.

As described in further detail below in connection with FIG. 9, the output signal OUT of the logic circuit LO of the bitcell 600 can be provided as an input to an adder tree.

Various aspects of the bitcell 600 described above are also aspects of bitcells described below in connection with FIGS. 6B-E, 7, and 8A-B. As such, some details may not be repeated below so as not to obscure the description of other features.

FIG. 6B is a cross-section of a device 605 including a heterogenous 3D digital CIM DRAM bitcell according to an embodiment.

The bitcell device 605 includes a stack of substrates in which a first substrate 610 and a second substrate 620 are combined by being stacked. For ease of reference, the first substrate 610 may be referred to as a lower or bottom substrate, and the second substrate 620 may be referred to as an upper or top substrate, but the terms “lower,” “bottom,” “upper,” and “top” do not imply a particular orientation.

The first substrate 610 includes an active region 618 in which a logic circuit (e.g., the logic circuit LO described above) is formed. The second substrate 620 includes an active region 628 in which a 1T1C DRAM memory circuit is formed. The 1T1C circuit includes an access transistor (e.g., the access transistor T_a described above) and a storage capacitor (e.g., the storage capacitor C_s described above).

In FIG. 6B, the first substrate 610 is combined with the second substrate 620 in a back-to-front arrangement in which a back side BS1 of the first substrate 610 faces and is bonded to a front side FS2 of the second substrate 620 by hybrid bonding. A front side FS1 of the first substrate 610 includes connecting bumps 656 (e.g., solder balls or the like) for connecting to an adjacent substrate (e.g., a wafer, PCB, or the like). Signals and/or power are routed to the back side BS1 of the first substrate 610 using through-silicon vias 658.

A hybrid bonding structure 650 includes a first dielectric layer 652 at the back side BS1 of the first substrate, which faces and is bonded to a second dielectric layer 682 at the front side FS2 of the second substrate 620. In some embodiments, the first and second dielectric layers 652, 652 include a silicon-containing dielectric such as silicon oxide, silicon oxynitride, or silane oxide. The hybrid bonding structure 650 further includes first interconnect elements 654 within the first dielectric layer 652 and exposed at a surface of the first dielectric layer 652, and second interconnect elements 684 within the second dielectric layer 682 and exposed at a surface of the second dielectric layer 682. The first interconnect elements 654 face and are bonded to the second interconnect elements 684. In some embodiments, the first and second interconnect elements 654, 684 are or include copper, and are bonded together by copper-to-copper bonding. In some embodiments, the first and second interconnect elements 654, 684 are connected to one or more conductive lines and vias within BEOL layers of the first and second substrates 610, 620.

In an embodiment, the first and second substrates 610, 620 have different functionalities and/or are fabricated using different wafer node technologies (i.e., different process nodes). In the case that the second process node is different from the first process node, the second process node can correspond to a different cost and/or PPA (power, performance, and area) of a fabricated element relative to the first process node. In a specific example, in the case that the second process node is different from the first process node, the second process node provides a minimum transistor gate length different from that of the first process node. The first substrate 610 can be a wafer, die, or other substrate. The second substrate 620 can be a wafer, die, or other substrate. The first substrate 610 can be the same type as, or a different type from, the second substrate 620. The second substrate 620 can be a die and the first substrate 610 can be a wafer, which structure may be referred to as a die-on-wafer or chip-on-wafer (CoW) structure. The second substrate 620 can be a first wafer and the first substrate 610 can be a second wafer, which structure may be referred to as a wafer-on-wafer (WoW) structure. In FIG. 6B, the first and second substrates 610, 620 are combined using hybrid bonding. However, the first and second substrates can be combined using any suitable stacking technology.

In FIG. 6B, two substrates are combined in a back-to-front arrangement. In other embodiments, two or more substrates are combined in a front-to-front arrangement, a back-to-back arrangement, or a combination of back-to-front, front-to-front, and back-to-back arrangements. In an embodiment, plural substrates each including 1T1C circuits are stacked on the back side BS2 of the second substrate 620. Increasing the number of substrates including 1T1C circuits increases overall memory density (see, e.g., FIG. 7).

In an embodiment, at least some of the interconnections formed by the first and second interconnect elements 654, 684 form electrical connections between a storage node (e.g., a terminal of the storage capacitor of the 1T1C circuit) on the second substrate 620 and the logic circuit (e.g., the logic circuit LO) on the first substrate 610. In FIG. 6B, the second substrate 620 is described as including a 1T1C circuit. However, memory structures other than a 1T1C circuit are usable.

Although FIG. 6B illustrates certain elements as being included in the first or lower substrate 610, such elements can be included in the second or upper substrate 620 instead. In other embodiments, elements that are illustrated as being included in the second or upper substrate 620 are included in the first or lower substrate 610 instead.

FIG. 6C is a flowchart of a method 6000 of fabricating a monolithic 3D digital CIM DRAM bitcell according to an embodiment.

The method 6000 includes an operation 6012 of forming one or more active devices of a logic circuit LO in an active region at a front side of a first substrate. In some embodiments, the active devices include one or more transistors, which in some examples are MOSFETs, PFETs and/or NFETs, CMOS transistors, finFETs, planar MOS transistors with raised source/drains, BJTs, high voltage transistors, high frequency transistors, or the like. The active devices form parts of the logic circuit LO, which in some embodiments is or includes logic gates such as NAND, NOR, AOI/OAI, or the like. In some embodiments, operation 6012 further includes forming an adder tree on the first substrate. In some embodiments, the first substrate is a single-crystal silicon substrate, a substrate having a silicon-on-insulator (SOI) structure, or another type of semiconductor substrate.

The method 6000 also includes an operation 6013 of forming a first dielectric layer and first interconnect elements on a back side of the first substrate. In some embodiments, the first dielectric layer includes a silicon-containing dielectric such as silicon oxide, silicon oxynitride, or silane oxide. In some embodiments, the first interconnect elements are or include copper. In some embodiments, at least some of the interconnect elements at the back side of the first substrate are connected to through-silicon vias that are formed to extend to the back side of the first substrate from BEOL layers on the front side of the first substrate. In some embodiments, operation 6013 further includes forming connecting bumps (e.g., solder balls or the like) on a front side of the first substrate, for connecting to an adjacent substrate (e.g., a wafer, interposer, PCB, or the like).

The method 6000 also includes an operation 6014 of forming a 1T1C circuit at a front side of a second substrate. Forming the 1T1C circuit includes forming an access transistor T_a in an active region, forming a storage capacitor C_s, and forming a storage node D. The operation 6014 includes forming a semiconductor layer, a gate dielectric layer, and a gate of the access transistor T_a. In an embodiment, the gate dielectric layer is formed of a metal oxide material, and the gate is formed of a polysilicon, a metal, or another conductive material. The operation 6014 includes forming capacitor electrodes facing a capacitor dielectric layer of the storage capacitor C_s. In an embodiment, the capacitor electrodes are formed of a metal or other conductive material. In an embodiment, the capacitor dielectric layer is formed of a material selectively used for a capacitor dielectric material, e.g., a high-k material. In some embodiments, operation 6014 further includes forming a row selector on the second substrate (see selection logic SL in FIG. 6E). In some embodiments, the second substrate is a single-crystal silicon substrate, a substrate having a silicon-on-insulator (SOI) structure, or another type of semiconductor substrate.

The method 6000 also includes an operation 6015 of forming a second dielectric layer and second interconnect elements on the front side of the second substrate, over the 1T1C circuit. In some embodiments, the second dielectric layer includes a silicon-containing dielectric such as silicon oxide, silicon oxynitride, or silane oxide. In some embodiments, the second interconnect elements are or include copper.

The method 6000 also includes an operation 6016 of inverting the first substrate and an operation 6018 of stacking and bonding the first and second substrates, such that the first and second substrates are combined in a back-to-front arrangement in which the back side of the first substrate faces and is bonded to the front side of the second substrate. A hybrid bonding process is used to bond the first and second substrates, whereby the first dielectric layer at the back side of the first substrate is arranged to face and bond with the second dielectric layer at the front side of the second substrate, and the first interconnect elements are arranged to face and bond with the second interconnect elements, e.g., by copper-to-copper bonding.

In an embodiment, the first and second substrates are formed to have different functionalities and/or are formed using different wafer node technologies (i.e., different process nodes). In the case that the second process node is different from the first process node, the second process node can correspond to a different cost and/or PPA (power, performance, and area) of a fabricated element relative to the first process node. In a specific example, in the case that the second process node is different from the first process node, the second process node provides a minimum transistor gate length different from that of the first process node. The first substrate can be a wafer, die, or other substrate. The second substrate can be a wafer, die, or other substrate. The first substrate can be the same type as, or a different type from, the second substrate. The second substrate can be a die and the first substrate can be a wafer, which structure may be referred to as a die-on-wafer or chip-on-wafer (CoW) structure. The second substrate can be a first wafer and the first substrate can be a second wafer, which structure may be referred to as a wafer-on-wafer (WoW) structure. In the method 6000, the first and second substrates are combined using hybrid bonding. However, the first and second substrates can be combined using any suitable stacking technology. Further, more than two dies can be combined. For example, a plurality of the second substrates can be stacked on the first substrate to increase a memory density. In an embodiment, a plurality of the second substrates is stacked on the first substrate, and each of the second substrates are formed to include one or more tri-state buffers.

In the method 6000, the first and second substrates are combined in a back-to-front arrangement. In other embodiments, two or more substrates are combined in a front-to-front arrangement, a back-to-back arrangement, or a combination of back-to-front, front-to-front, and back-to-back arrangements. In an embodiment, plural substrates each including 1T1C circuits are stacked on the back side of the second substrate. Increasing the number of substrates including 1T1C circuits increases overall memory density (see, e.g., FIG. 7).

In an embodiment, at least some of the interconnections formed by the first and second interconnect elements form electrical connections between a storage node (e.g., a terminal of the storage capacitor of the 1T1C circuit) on the second substrate and the logic circuit (e.g., the logic circuit LO) on the first substrate. In the method 6000, a 1T1C circuit is formed on the second substrate. However, memory structures other than a 1T1C circuit are usable.

Although the method 6000 describes certain elements as being formed on the first or lower substrate, such elements can be formed on the second or upper substrate instead. In other embodiments, elements that are described as being formed on the second or upper substrate are instead formed on the first or lower substrate.

FIG. 6D is a circuit diagram of a heterogenous 3D digital CIM DRAM bitcell 600′ according to an embodiment.

In an embodiment, the bitcell 600′ is included in or is the memory cell 117 described in connection with FIG. 1.

The bitcell 600′ is substantially the same as the bitcell 600 with the exception that two 1T1C circuits are provided on the second substrate, and a logic circuit LO′ on the first substrate has a plurality of corresponding inputs. In the bitcell 600′, each of the 1T1C circuits is the same as the 1T1C circuit of FIG. 6A.

In FIG. 6D, the bitcell 600′ includes two 1T1C circuits on the second substrate. In other embodiments, the bitcell 600′ includes three or more than three 1T1C circuits on the second substrate. Also, in FIG. 6A the logic circuit LO′ has three inputs (the input signal IN and two signals from the 1T1C circuits) and in some embodiments the logic circuit LO′ has four or more than four inputs.

FIG. 6E is a circuit diagram of a heterogenous 3D digital CIM DRAM bitcell 600″ according to an embodiment.

In an embodiment, the bitcell 600″ is included in or is the memory cell 117 described in connection with FIG. 1.

The bitcell 600″ is substantially the same as the bitcell 600 with the exception that selection logic SL is inserted on the second substrate between the storage node D and the input of the logic circuit LO (on the first substrate). The selection logic SL is used to switch between different sets of weights. The selection logic SL selects among rows. In an embodiment, the selection logic SL reduces a frequency of memory access, and results in lower power demands and lower latency relative to a device that does not include the selection logic SL.

The selection logic SL in the bitcell 600″ includes a NOR gate, which is, or is part of, logic operating as a multiplexer. It will be appreciated that the selection logic SL can be or include logic other than a NOR gate, and can select among two or more than two bitcells.

In the bitcell 600″, the selection logic SL is included on the second substrate, i.e., the second substrate includes bitcells and the selection logic SL. However, in other embodiments the selection logic SL is included on the first substrate (not shown in FIG. 6E).

In an embodiment, the selection logic SL is formed as FEOL devices on the second substrate. In an embodiment, the selection logic SL is fabricated on the second substrate using a process node that is more mature than a process node that is used to fabricate the logic circuit LO and/or other devices on the first substrate. Implementing the selection logic SL in a more mature node saves cost without reducing performance in a device in which weight switching does not happen frequently and can tolerate lower speed.

In an embodiment, three or more than three substrates are stacked. For example, the second substrate is a plurality of second substrates each including bitcells and selection logic SL, and each coupled to the logic circuit LO on the first substrate. Increasing the number of second substrates in the stack increases overall memory density.

FIG. 7 is a circuit diagram of a 3D digital CIM DRAM bitcell 700 according to an embodiment.

In an embodiment, the bitcell 700 is included in or is the memory cell 117 described in connection with FIG. 1.

The bitcell 700 is substantially the same as the bitcell 600 with the exceptions that a plurality of second substrates is provided (denoted as second, third, . . . , n^{th} substrates, by way of example), and a tristate buffer TSB is inserted (on each of the plurality of second substrates) between the storage node D and the input of the logic (on the first substrate).

In the bitcell 700, the tristate buffers TSB₀ . . . TSBₙ (on second through n^{th} substrates) share a signal line. This configuration reduces the number of interconnects between substrates to conserve interconnect resources, e.g., reducing interconnect density.

In an embodiment, the devices on the plurality of second substrates are fabricated using a process node that is more mature than a process node that is used to fabricate the devices on the first substrate. Implementing the second substrates in a more mature node can save cost without reducing performance in a device in which weight switching does not happen frequently and can tolerate lower speed.

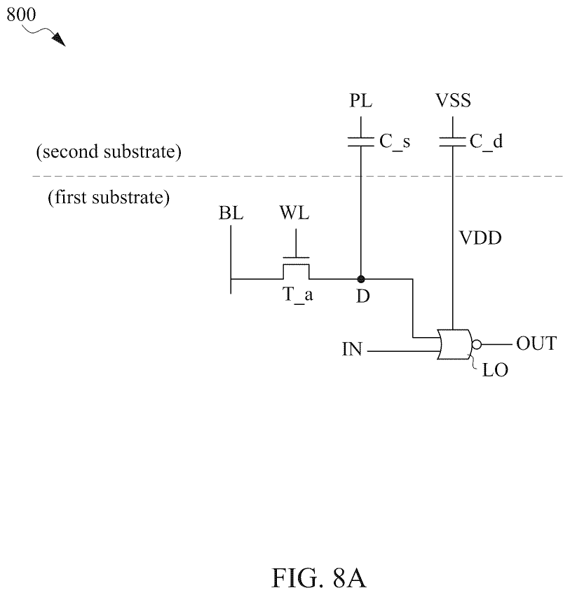

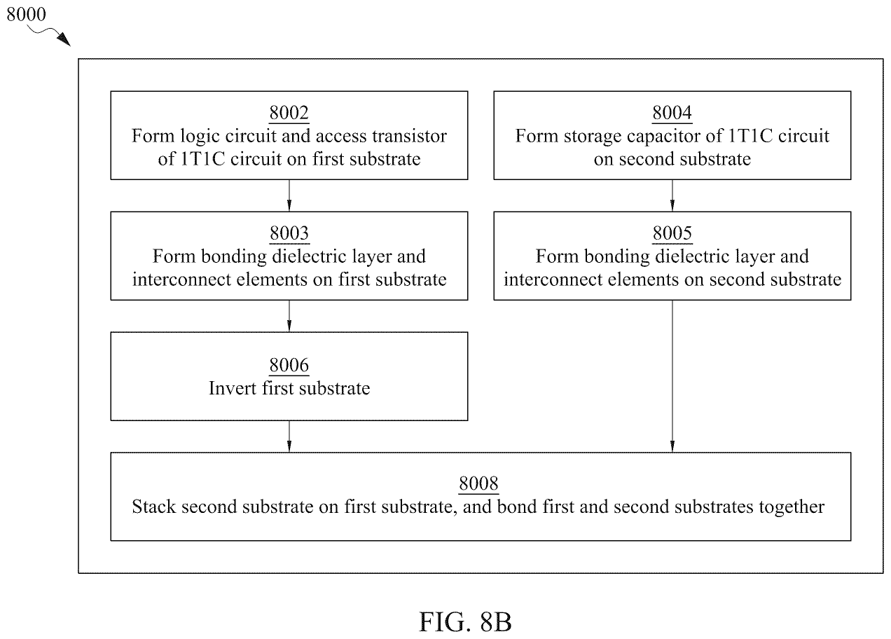

FIG. 8A is a circuit diagram of a 3D digital CIM DRAM bitcell 800 according to an embodiment.

In an embodiment, the bitcell 800 is included in or is the memory cell 117 described in connection with FIG. 1.

In the bitcell 800, the second substrate includes a first capacitor C_s, the first substrate includes an access transistor T_a, and the first capacitor C_s and the access transistor T_a form a 1T1C circuit having a storage node D, which is tapped on the first substrate to provide an input signal to the logic circuit LO on the first substrate. In contrast to the bitcell 600, in the bitcell 800 the second substrate does not include the access transistor T_a of the 1T1C circuit.

In the bitcell 800, the storage capacitor C_s of the 1T1C circuit is on the second substrate, the access transistor T_a and the storage node D are on the first substrate, and an electrical connection extends from a first terminal of the storage capacitor C_s to the storage node D. In some embodiments, the electrical connection is or includes a hybrid bonding or bumpless interconnect, a microbump interconnect, or the like, as described above.

In the bitcell 800, the second substrate also includes a second capacitor C_d implemented as a decoupling capacitor in a power connection to the logic circuit LO, which can improve power integrity. Each of the first capacitor C_s and the second capacitor C_d is coupled to the first substrate by a corresponding electrical connection (e.g., a corresponding hybrid bonding or bumpless interconnect, microbump interconnect, or the like).

In an embodiment, the storage capacitor C_s and the decoupling capacitor C_d are fabricated as FEOL devices on the second substrate, and the access transistor T_a and the logic circuit LO on the first substrate include one or more transistors fabricated as FEOL devices. In an embodiment, the storage capacitor C_s and the decoupling capacitor C_d are fabricated as BEOL devices on the second substrate (e.g., in metal layers on the second substrate), and the access transistor T_a and the logic circuit LO on the first substrate include one or more transistors fabricated as FEOL devices.

In an embodiment, the bitcell 800 is a passive-on-active structure in which the second substrate includes passive devices (capacitors) and the first substrate includes active devices (e.g., transistors and the like). In an embodiment, the second, passive substrate is entirely free of active devices. In an embodiment, the second, passive substrate is substantially free of active devices. In an example embodiment, the first, active substrate includes all active devices (e.g., transistors and the like) of the bitcells.

FIG. 8B is a flowchart of a method 8000 of fabricating a monolithic 3D digital CIM DRAM bitcell using active and passive substrates, according to an embodiment.

The method 8000 includes an operation 8002 of forming one or more active devices of a logic circuit LO in an active region at a front side of a first substrate. In some embodiments, the active devices include one or more transistors, which in some examples are MOSFETs, PFETs and/or NFETs, CMOS transistors, finFETs, planar MOS transistors with raised source/drains, BJTs, high voltage transistors, high frequency transistors, or the like. The active devices form parts of the logic circuit LO, which in some embodiments is or includes logic gates such as NAND, NOR, AOI/OAI, or the like. In some embodiments, operation 8002 further includes forming an adder tree on the first substrate. In some embodiments, the first substrate is a single-crystal silicon substrate, a substrate having a silicon-on-insulator (SOI) structure, or another type of semiconductor substrate.

Operation 8002 further includes forming an access transistor T_a of a 1T1C circuit on the first substrate. Forming the access transistor T_a includes forming a gate dielectric layer and a gate over a semiconductor layer on the first substrate. In an embodiment, the gate dielectric layer is formed of a metal oxide material, and the gate is formed of a polysilicon, a metal, or another conductive material.

The method 8000 also includes an operation 8003 of forming a first dielectric layer and first interconnect elements on a back side of the first substrate. In some embodiments, the first dielectric layer includes a silicon-containing dielectric such as silicon oxide, silicon oxynitride, or silane oxide. In some embodiments, the first interconnect elements are or include copper. In some embodiments, at least some of the interconnect elements at the back side of the first substrate are connected to through-silicon vias that extend to the back side of the first substrate from BEOL layers on the front side of the first substrate. In some embodiments, operation 8003 further includes forming connecting bumps (e.g., solder balls or the like) on a front side of the first substrate, for connecting to an adjacent substrate (e.g., a wafer, interposer, PCB, or the like).

The method 8000 also includes an operation 8004 of forming a storage capacitor C_s of the 1T1C circuit at a front side of a second substrate. Forming the storage capacitor C_s includes forming capacitor electrodes facing a capacitor dielectric layer of the storage capacitor C_s. In an embodiment, the capacitor electrodes are formed of a metal or other conductive material. In an embodiment, the capacitor dielectric layer is formed of a material selectively used for a capacitor dielectric material, e.g., a high-k material. In some embodiments, the second substrate is a single-crystal silicon substrate, a substrate having a silicon-on-insulator (SOI) structure, or another type of semiconductor substrate. In some embodiments, the second substrate is a passive substrate free of transistors, and/or is formed of a material other than a semiconductor material. In some embodiments, a decoupling capacitor C_d for a power supply line to the logic circuit LO on the first substrate is further formed on the second substrate in operation 8004.

The method 8000 also includes an operation 8005 of forming a second dielectric layer and second interconnect elements on the front side of the second substrate. In some embodiments, the second dielectric layer includes a silicon-containing dielectric such as silicon oxide, silicon oxynitride, or silane oxide. In some embodiments, the second interconnect elements are or include copper.

The method 8000 also includes an operation 8006 of inverting the first substrate and an operation 8008 of stacking and bonding the first and second substrates, such that the first and second substrates are combined in a back-to-front arrangement in which the back side of the first substrate faces and is bonded to the front side of the second substrate. A hybrid bonding process is used to bond the first and second substrates, whereby the first dielectric layer at the back side of the first substrate is arranged to face and bond to the second dielectric layer at the front side of the second substrate, and the first interconnect elements are arranged to face and bonded to the second interconnect elements, e.g., by copper-to-copper bonding.

In an embodiment of the method 8000, the first substrate is formed to have active devices and the second substrate is formed to have only passive devices, e.g., storage capacitors and decoupling capacitors. In some embodiments, the first and second substrates are formed using different wafer node technologies (i.e., different process nodes). In the case that the second process node is different from the first process node, the second process node can correspond to a different cost and/or PPA (power, performance, and area) of a fabricated element relative to the first process node. The first substrate can be a wafer, die, or other substrate. The second substrate can be a wafer, die, or other substrate. The first substrate can be the same type as, or a different type from, the second substrate. The second substrate can be a die and the first substrate can be a wafer, which structure may be referred to as a die-on-wafer or chip-on-wafer (CoW) structure. The second substrate can be a first wafer and the first substrate can be a second wafer, which structure may be referred to as a wafer-on-wafer (WoW) structure. In the method 8000, the first and second substrates are combined using hybrid bonding. However, the first and second substrates can be combined using any suitable 3D stacking technology. Further, more than two dies can be combined. For example, a plurality of the second substrates can be stacked on the first substrate to increase a memory density. In an embodiment, a plurality of the second substrates is stacked on the first substrate, and each of the second substrates are formed to include one or more tri-state buffers.

In the method 8000, the first and second substrates are combined in a back-to-front arrangement. In other embodiments, two or more substrates are combined in a front-to-front arrangement, a back-to-back arrangement, or a combination of back-to-front, front-to-front, and back-to-back arrangements.

In an embodiment, at least some of the interconnections formed by the first and second interconnect elements form electrical connections between the storage capacitor C_s on the second substrate and the access transistor T_a on the first substrate, and at least some others of the interconnections formed by the first and second interconnect elements form electrical connections between the decoupling capacitor C_d on the second substrate and the logic circuit LO on the first substrate.

Although the method 8000 describes certain elements as being formed on the first or lower substrate, such elements can be formed on the second or upper substrate instead. In other embodiments, elements that are described as being formed on the second or upper substrate are instead formed on the first or lower substrate.

FIG. 9 is a schematic diagram of a memory macro 900 according to an embodiment.

The memory macro 900 includes one or more MAC arrays 905 (e.g., MAC arrays 905_1, 905_2, 905_3, . . . , 905_n, where n is a positive integer). Each MAC array 905 includes one or more bitcell arrays 910 each having a plurality of bitcells, which are the bitcells 500, 505, 600′, 600″, 605, 700, and/or 800 in some embodiments.

Each MAC array 905 includes an adder tree 920. The adder tree 920 includes a plurality of adders arranged in multiple stages. The adder tree 920 receives, as one or more inputs, one or more outputs from the bitcell array 910 (the outputs being denoted as D[1], D[2], . . . , D[i], where i is a positive integer). In some embodiments, the outputs are based on signals ROW[N:0] provided to the NOR gates in the bitcell array 910 to select weight values. The adder tree 920 accumulates the results output from the logic circuits of the bitcell array 910. In some embodiments, the adder tree 920 accumulates the results that are output as the output signals OUT from the logic circuits LO of the bitcells 500, 505, 600′, 600″, 605, 700, and/or 800. In some embodiments, the adder tree 920 accumulates the results of an operation by the logic circuit LO of the bitcells 500, 505, 600′, 600″, 605, 700, and/or 800 (e.g., a NOR operation) as a partial sum result. In some embodiments, the adder tree 920 includes NOR gates to perform bitwise multiplication for the output of the bitcells in the bitcell array 910 (D[1]-D[i]) and input signals IN[M:0]. The adder tree 920 is coupled to a bitshifter and final accumulator 930 (denoted “shift+sum” in FIG. 9). In an embodiment, the bitshifter and accumulator 930 use a two's complement of a partial sum result to handle a signed input calculation. In some embodiments, the adder tree 920 accumulates the results of an operation by the logic circuit LO of the bitcells 500, 505, 600′, 600″, 605, 700, and/or 800 (e.g., a NOR operation) as a partial sum result, the bitshifter compensates for the bit significance of an input, and a final MAC result is obtained as an output from the accumulator.

In an embodiment, the bitcell array 910 is the memory array 112 described in connection with FIG. 1, and the adder tree, the bitshifter, and the accumulator are included in the output circuit 115 of the memory macro 110 described in connection with FIG. 1.

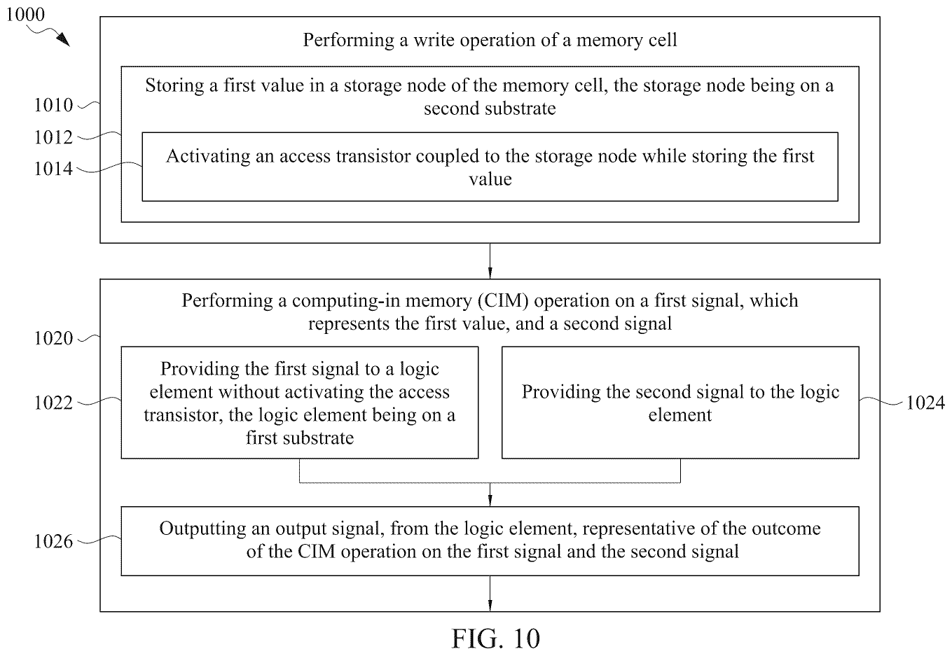

FIG. 10 is a flowchart of a method 1000 of operating a circuit according to an embodiment.

The method 1000 includes a first operation 1010 of writing to a memory cell of a memory cell array.

In some embodiments, the memory cell is or includes the bitcells 500, 505, 600′, 600″, 605, 700, and/or 800, and writing to the memory cell includes an operation 1012 of storing a first value in the storage node. In an example embodiment, the memory cell stores a value corresponding to a 0 or a 1 as the first value.

In an example embodiment, writing the first value to the storage node includes an operation 1014 of activating an access transistor of the bitcell, to thereby couple the storage node to a bit line. In an example embodiment, activating the access transistor includes applying a signal from a wordline to a gate of the access transistor.

The method 1000 includes a second operation 1020 of performing a computing-in-memory (CIM) operation, in the bitcell, on a first signal, which represents the first value, and a second signal. The CIM operation in the bitcell is one of the CIM operations described above, e.g., mathematical operations, logical operations, combination thereof, or the like, including a NOR operation, an AOI operation, an OAI operation, a MAC operation, and/or other operations on the first signal.

In an example embodiment, the second operation 1020 includes an operation 1022 of providing the first signal, which represents the first value stored in the storage node of the bitcell, to a logic element in the bitcell without activating the access transistor of the bitcell. In an example embodiment, the logic element in the bitcell has an input that is directly coupled to the storage node of the bitcell, i.e., without being controlled by the access transistor or another transistor. In an example embodiment, the phrase “without activating the access transistor” refers to not changing a state of a signal applied to a gate of the access transistor. In an example embodiment, the phrase “without activating the access transistor” refers to maintaining the access transistor in a non-conductive state such that the storage node of the bitcell is electrically isolated from the bitline. In an example embodiment, in the operation 1022, the storage node is located on a second substrate of a stack of substrates, and the logic element is located on a first substrate of the stack of substrates.

In an example embodiment, the second operation also includes an operation 1024 of providing the second signal to the logic element. The first and second signals are provided to first and second inputs, respectively, of the logic element.

In an example embodiment, the second operation 1020 includes an operation 1026 of outputting an output signal, from the logic element in the bitcell, that is representative of the output or outcome of the CIM operation performed in the bitcell on the first signal and the second signal.

In some embodiments, a memory includes a logic circuit having a first input, a second input, and an output; and a memory circuit including: a transistor coupled to the logic circuit, the transistor having a semiconductor layer including a source and a drain; and a storage node having a first connection, a second connection, and a third connection. The source or the drain of the transistor is coupled to the first connection of the storage node, the logic circuit includes one or more transistors in an active region of a substrate, the one or more transistors being front-end of line (FEOL) devices, and the semiconductor layer and the storage node are in back-end of line (BEOL) layers over the substrate.

In some embodiments, a memory having stacked substrates includes a logic circuit having a first input, a second input, and an output; and a memory circuit, including: a transistor having a source and a drain; and a storage node having a first connection, a second connection, and a third connection. The source or the drain of the transistor is coupled to the first connection of the storage node. The logic circuit is on a first substrate. The transistor and the storage node are on a second substrate. The first and second substrates are coupled together in a stack.

In some embodiments, a memory having stacked substrates includes a logic circuit having a first input, a second input, and an output; and a memory circuit that includes a storage capacitor and a transistor. The transistor and the logic circuit are on a first substrate, and the storage capacitor is on a second substrate. The storage capacitor has first and second terminals. The transistor has a source and a drain, and the source or the drain is coupled to the first terminal of the storage capacitor by a conductor that includes an interconnect connecting the first and second substrates. The first input of the logic circuit is coupled to the first terminal of the storage capacitor.

In some embodiments, a method of operating a memory having first and second substrates includes storing a first value in a memory circuit of the memory, wherein the memory circuit includes a storage node and a transistor on the second substrate, and the storage node has a first connection, a second connection, and a third connection, the transistor has a source and a drain, and the source or the drain is coupled to the first connection of the storage node; providing a first signal representative of the first value from the second connection of the storage node to a first input of a logic circuit on the first substrate via a conductor that includes an interconnect connecting the first and second substrates together in a stack; and performing a logical operation using the logic circuit, an output of the logic circuit corresponding to a result of the logical operation on a second signal received at a second input of the logic circuit and the first signal received at the first input of the logic circuit.

In some embodiments, a method of fabricating a memory includes forming a logic circuit having a first input, a second input, and an output, the forming the logic circuit including forming a first transistor in an active region of a substrate, the first transistor being a front-end of line (FEOL) device; and forming a plurality of back-end of line (BEOL) layers over the substrate, the forming a plurality of back-end of line (BEOL) layers over the substrate including: forming a semiconductor layer of a second transistor in the BEOL layers, the semiconductor layer including a source and a drain, forming an electrical connection between the first input of the logic circuit and one of the source or the drain, forming a storage node in the BEOL layers, and forming an electrical connection between the storage node and the one of the source or the drain.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A memory comprising:
a logic circuit having a first input, a second input, and an output; and
a memory circuit including:
a transistor coupled to the logic circuit, the transistor having a semiconductor layer including a source and a drain; and
a storage node having a first connection, a second connection, and a third connection,
wherein:
the source or the drain of the transistor is coupled to the first connection of the storage node,
the logic circuit includes one or more transistors in an active region of a substrate, the one or more transistors being front-end of line (FEOL) devices, and
the semiconductor layer and the storage node are in back-end of line (BEOL) layers over the substrate.

2. The memory of claim 1, wherein the first input of the logic circuit is coupled to the second connection of the storage node by one or more conductors in the BEOL layers.

3. The memory of claim 1, wherein:
the memory circuit further includes a capacitor in the BEOL layers,
the third connection of the storage node is coupled to a first terminal of the capacitor, and
a second terminal of the capacitor is coupled to a reference voltage.

4. The memory of claim 1, wherein:
the BEOL layers include a plurality of metal layers, and
at least one metal layer of the plurality of metal layers is at a level that is between the semiconductor layer and the substrate.

5. The memory of claim 1, wherein:
the memory circuit includes the transistor, the storage node, and a capacitor,
the BEOL layers include a plurality of metal layers, and
at least one metal layer of the plurality of metal layers is at a level that is between the capacitor and the substrate.

6. The memory of claim 1, wherein the memory circuit is a one transistor, one capacitor circuit.

7. The memory of claim 6, wherein the memory circuit is free of a transistor in the active region.

8. The memory of claim 1, wherein the transistor is configured to operate at a higher voltage than the logic circuit.

9. The memory of claim 1, wherein:
the memory includes a plurality of memory circuits, each of the memory circuits having a transistor, a capacitor, and a storage node in the BEOL layers, and
the memory includes a plurality of logic circuits corresponding to the plurality of memory circuits, each of the logic circuits having one or more transistors in the active region.

10. The memory of claim 9, wherein:
the substrate includes an adder tree, and
outputs of the plurality of logic circuits are coupled to inputs of the adder tree.

11. The memory of claim 1, wherein the logic circuit is configured to perform a logical operation on a signal received at the second input and a value stored in the memory circuit and received at the first input.

12. The memory of claim 1, wherein:
the memory circuit is a first memory circuit,
the memory further comprises a second memory circuit having a transistor, a capacitor, and a storage node in the BEOL layers,
the logic circuit further includes a third input,
the first input of the logic circuit is coupled to the storage node of the first memory circuit, and
the third input of the logic circuit is coupled to the storage node of the second memory circuit.

13. A memory having stacked substrates, the memory comprising:
a logic circuit having a first input, a second input, and an output; and
a memory circuit that includes a storage capacitor and a transistor,
wherein:
the transistor and the logic circuit are on a first substrate, and the storage capacitor is on a second substrate,
the storage capacitor has first and second terminals,
the transistor has a source and a drain, and the source or the drain is coupled to the first terminal of the storage capacitor by a conductor that includes an interconnect connecting the first and second substrates, and
the first input of the logic circuit is coupled to the first terminal of the storage capacitor.

14. The memory of claim 13, wherein the first input of the logic circuit is coupled to the first terminal of the storage capacitor by the conductor.

15. The memory of claim 13, wherein:
the memory includes a plurality of memory circuits with their transistors on the first substrate and their storage capacitors on the second substrate, and
each storage capacitor of the plurality of memory circuits is coupled to a corresponding transistor with a corresponding interconnect connecting the first and second substrates.

16. The memory of claim 15, wherein each storage capacitor of the plurality of memory circuits has a first terminal coupled to a corresponding logic circuit on the first substrate,
the memory further comprising an adder tree, outputs of the logic circuits being coupled to inputs of the adder tree.

17. The memory of claim 13, wherein the interconnect that couples the source or the drain of the transistor to the first terminal of the storage capacitor is a first interconnect,
the memory further comprising a decoupling capacitor on the second substrate and a second interconnect that connects the first and second substrates, a terminal of the decoupling capacitor being coupled to a power terminal of the logic circuit with the second interconnect.

18. The memory of claim 13, wherein the second terminal of the storage capacitor is coupled to a reference voltage.

19. A method of fabricating a memory, the method comprising:
forming a logic circuit having a first input, a second input, and an output, the forming the logic circuit including:
forming a first transistor in an active region of a substrate, the first transistor being a front-end of line (FEOL) device; and
forming a plurality of back-end of line (BEOL) layers over the substrate, the forming a plurality of back-end of line (BEOL) layers over the substrate including:
forming a semiconductor layer of a second transistor in the BEOL layers, the semiconductor layer including a source and a drain,
forming an electrical connection between the first input of the logic circuit and one of the source or the drain,
forming a storage node in the BEOL layers, and
forming an electrical connection between the storage node and the one of the source or the drain.

20. The method of claim 19, wherein the forming a plurality of back-end of line (BEOL) layers over the substrate further includes:
forming a capacitor in the BEOL layers, and
forming an electrical connection between a terminal of the capacitor and the one of the source or the drain.
